(19) United States
(12) Patent Application Publication
(10) Pub. No.: US 2007/0272562 A1
(43) Pub. Date: Nov. 29, 2007

(54) Electrolytic Processing Apparatus and Electrolytic Processing Method

(76) Inventors: Ikutaro Noji, Tokyo (JP); Hozumi Yasuda, Tokyo (JP); Takeshi Iizumi, Tokyo (JP); Kazuto Hirokawa, Tokyo (JP); Itsuki Kobata, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/560,623

(22) PCT Filed: Jul. 14, 2004
(86) PCT No.: PCT/JP04/10362

§ 371 Date: Feb. 8, 2007

(30) Foreign Application Priority Data
Jul. 15, 2003 (JP) 2003-197408
Jan. 14, 2004 (JP) 2004-007123

(51) Int. Cl. H01L 21/3063

(52) U.S. Cl. 205/686; 204/225

(57) ABSTRACT

The present invention provides an electrolytic processing apparatus and an electrolytic processing method which can effectively prevent the formation of pits that would impair the quality of the processed product. The electrolytic processing apparatus including: a processing electrode (210) for processing a workpiece; a feeding electrode (212) for feeding electricity to the workpiece; a power source (232) for applying a voltage between the processing electrode (210) and the feeding electrode (212); a pressure tight container (200) housing the processing electrode (210) and the feeding electrode (212) therein; and a high-pressure liquid supply system (204) for supplying a high-pressure liquid into the pressure tight container (210).

### TECHNICAL FIELD

This invention relates to an electrolytic processing apparatus and an electrolytic processing method, and more particularly to an electrolytic processing apparatus and an electrolytic processing method useful for processing a conductive material formed in a surface of a substrate, such as a semiconductor wafer, or for removing impurities adhering to a surface of a substrate.

### BACKGROUND ART

In recent years, instead of using aluminum or aluminum alloys as a material for forming circuits on a substrate such as a semiconductor wafer, there is an eminent movement towards using copper (Cu) which has a low electric resistivity and high electromigration resistance. Copper interconnects are generally formed by filling copper into fine recesses formed in a surface of a substrate. Various techniques for forming such copper interconnects are known including chemical vapor deposition, sputtering, and plating. According to any such technique, a copper film is formed in a substantially entire surface of a substrate, followed by removal of unnecessary copper by chemical mechanical polishing (CMP).

FIGS. 1 A through 1C illustrate, in sequence of process steps, an example of forming such a substrate W having copper interconnects. As shown in FIG. 1A, an insulating film 2, such as an oxide film of SiO₂ or a film of low-k material, is deposited on a conductive layer 1a in which semiconductor devices are formed, which is formed on a semiconductor base 1. Contact holes 3 and interconnect trenches 4 are formed in the insulating film 2 by the lithography/etching technique. Thereafter, a barrier layer 5 of TaN or the like is formed on a surface of the insulating film 2, and a seed layer 7 as an electric supply layer for electroplating is formed on the barrier layer 5 by sputtering or CVD, or the like.

Then, as shown in FIG. 1B, copper plating is performed onto the surface of the substrate W to fill the contact holes 3 and the trenches 4 with copper and, at the same time, deposit a copper film 6 on the insulating film 2. Thereafter, the copper film 6, the seed layer 7 and the barrier layer 5 on the insulating film 2 are removed by chemical mechanical polishing (CMP) or the like so as to make the surface of the copper film 6 filled in the contact holes 3 and the trenches 4, and the surface of the insulating film 2 lie substantially on the same plane. Interconnects composed of the copper film 6 as shown in FIG. 1C are thus formed.

Components in various types of equipments have recently become finer and have required higher accuracy. As sub-micro manufacturing technology has commonly been used, the properties of materials are largely influenced by the processing method. Under these circumstances, in such a conventional machining method that a desired portion in a workpiece is physically destroyed and removed from the surface thereof by a tool, a large number of defects may be produced to deteriorate the properties of the workpiece. Therefore, it becomes important to perform processing without deteriorating the properties of the materials.

Some processing methods, such as chemical polishing, electrolytic processing, and electrolytic polishing, have been developed in order to solve this problem. In contrast with the conventional physical processing, these methods perform removal processing or the like through chemical dissolution reaction. Therefore, these methods do not suffer from defects, such as formation of an altered layer and dislocation, due to plastic deformation, so that processing can be performed without deteriorating the properties of the materials.

In the case of the above-mentioned electrolytic processing or electrolytic polishing, the process proceeds through an electrochemical interaction between a workpiece and an electrolytic solution (aqueous solution of NaCl, NaNO₃, HF, HCl, HNO₃, NaOH, etc.). Since an electrolytic solution containing such an electrolyte must be used, contamination of a workpiece with the electrolyte cannot be avoided.

Further, a method has been reported which performs CMP processing simultaneously with plating, viz. chemical mechanical electrolytic polishing. According to this method, the mechanical processing is carried out to the growing surface of a plating film, causing the problem of denaturing of the resulting film.

Electrolytic metal processing methods, which are improved in environmental burden, contamination of a processed product, danger in operation, etc., have recently been developed (see, for example, Japanese Patent Laid-Open Publication Nos. 2000-52235 and 2001-64799). These electrolytic processing methods use pure or ultrapure water in carrying out electrolytic processing. Since pure water or ultrapure water hardly passes electricity therethrough, the processing methods use an ion exchanger disposed between a workpiece serving as an anode and a processing electrode serving as a cathode to carry out electrolytic processing of the workpiece. Since the workpiece, the ion exchanger and the processing electrode are all put in pure water or ultrapure water atmosphere, the environmental burden problem and the workpiece contamination problem can be remarkably reduced. Further, the metal of the workpiece is removed as metal ions through the electrolytic reaction, and the dissolved ions are held in the ion exchanger. This can further reduce contamination of the workpiece and the liquid (pure water or ultra pure water) itself. Such a processing method, therefore, is considered as an ideal electrolytic processing method.

As described above, according to the electrolytic processing method which processes a workpiece by using an ion exchanger and supplying ultrapure water, contamination of the workpiece can be prevented and environmental burden can be remarkably reduced. Further, the electrolytic processing method can provide various metal parts with a specular gloss surface, and can also eliminate the use of a cutting oil, a slurry containing a polishing agent, an electrolytic solution, etc. which are necessary for the conventional mechanical metal processing for finishing methods.

Though the electrolytic processing method using an ion exchanger has the above advantages, it is known that depending upon the type of workpiece, the processing conditions, etc., pits (small holes) can be formed in the processed surface. The pits are such fine holes invisible to the naked eye that they may be present even when the processed surface shows a specular gloss. Thus, the pits are fine holes that can be only determined through analysis by a scanning electron microscope, a laser microscope, an atomic force microscope, and the like.

Such pits, when formed in the finished surface of an ordinary mechanical part, may not adversely affect the appearance of the article. However, when pits are formed in a sealing surface of e.g. a vacuum device or a pressure device that requires a high degree of sealing, the desired vacuum or pressure may not be obtained. Further, the pits can promote corrosion of the metal. Also in the case of a semiconductor device, the formation of pits may exert various adverse influences.

Further, in electrolytic processing using an ion exchanger and employing a certain electrode system (a feeding electrode and a processing electrode), the processing rate changes with a change in the relative speed between a workpiece and the processing electrode. In particular, as shown in FIG. 2, the processing rate is low when carrying out processing with a fast relative speed between the work piece and the processing electrode. Adversely, the processing rate is high when carrying out processing with a slow relative speed between the workpiece and the processing electrode.

In this regard, a hydroplaning phenomenon may be a first factor. In particular, as shown in FIGS. 3A and 3B, when electrolytic processing is carried out by supplying a liquid such as pure water, preferably ultrapure water between a workpiece W and a processing electrode 300 while keeping the workpiece W and an ion exchanger (ion-exchange membrane) 302 covering the surface of the processing electrode 300 in contact with each other and moving them relative to each other, and applying a voltage between the workpiece W and the processing electrode 300, a water film 304a or 304b is formed between the ion exchanger 302 and the processing surface of the workpiece W (hydroplaning phenomenon). The water film 304a shown in FIG. 3A, which is formed during electrolytic processing as carried out with as low relative speed between the workpiece W and the processing electrode 300 (ion exchanger 302), is thinner than the water film 304b shown in FIG. 3B, which is formed during electrolytic processing as carried out with a fast relative speed between the workpiece W and the processing electrode 300 (ion exchanger 302). Since the water film 304a or 304b is an insulator, the electrolytic efficiency decreases and the processing rate decreases as the thickness of the water film increases.

Arise in the electric conductivity due to reaction products may be a second factor. In particular, in carrying out electrolytic processing in the same manner as shown in FIGS. 3A and 3B, when the relative speed between the workpiece W and the processing electrode 300 (ion exchanger 302) is slow, the residence time of the processing electrode 300 per unit area of the processing surface of the workpiece W is relatively long and release of reaction products 306 (copper ion/copper oxide, OH⁻ generated by electrolysis of pure water, etc.) becomes poor, as shown in FIG. 4A. Accordingly, as compared to the case of fast relative speed between the workpiece W and the processing electrode 300 (ion exchanger 302) as shown in FIG. 4B, the concentration of the reaction products 306 is high. A higher concentration of the reaction products 306 increases the electric conductivity, thus enhancing the electrolytic efficiency and increasing the processing rate.

When the formation of interconnects as shown in FIG. 1C by removal and flattening of the extra film 6 on the insulating film 2, shown in FIG. 1B, is carried out by the above-described electrolytic processing using an ion exchanger, it is known that the processing amount and the residual level difference in the surface being processed generally have a relationship as shown in FIG. 5: the level difference decreases as the processing amount increases. The degree of the decrease in level difference varies depending on the initial film thickness of the workpiece, the initial level difference, the processing conditions, etc.

The effect of elimination of level difference as shown in FIG. 5 tends to be lower as the processing rate is higher in electrolytic processing using an ion exchanger. It is thus considered that when processing a workpiece W while moving the workpiece W and the processing electrode 300 (ion exchanger 302) relative to each other, the processing rate decreases as the relative speed increases, as described above, and the level difference elimination effect increases with a decrease in the processing rate. Enhancement of the level difference elimination effect with an increase in the relative speed between the workpiece W and the processing electrode 300 (ion exchanger 302) is inferable also from the behavior of ion exchanger.

In this regard, a rise in the electric conductivity may be a first factor. In particular, when the relative speed between the workpiece W and the processing electrode 300 (ion exchanger 302) is slow (the processing rate is high) as with the above-described case shown in FIG. 4A, the concentration of the processing products 306 is high, as shown in FIG. 6A, as compared to the case where the relative speed between the workpiece W and the processing electrode 300 (ion exchanger 302) is fast (the processing rate is low) as shown in FIG. 6B. Thus, the concentration of the reaction products in the recesses of a pattern is higher and a difference in processing rate between the raised portions and the recessed portions of the pattern is smaller, and therefore, the level difference elimination effect is lower.

A change in the apparent modules of elasticity of ion exchanger may be a second factor. In particular, when the relative speed between the workpiece W and the processing electrode 300 (ion exchanger 302) is slow, as shown in FIG. 7A, the apparent modules of elasticity of the ion exchanger 302 is low as compared to the case of fast relative speed between the workpiece W and the processing electrode 300 (ion exchanger 302) as shown in FIG. 7B. Thus, the deformation of the ion exchanger 302 is larger, so that it intrudes more deeply into the recesses of a pattern. This narrows the distance between the recessed portions of the pattern and the ion exchanger 302, making a difference in processing rate between the raised portions and the recessed portions of the pattern smaller and thus lowering the level difference elimination effect.

### DISCLOSURE OF INVENTION

The present invention has been made in view of the above situation in the background art. It is therefore a first object of the present invention to provide an electrolytic processing apparatus and an electrolytic processing method which can effectively prevent the formation of pits that would impair the quality of the processed product.

It is a second object of the present invention to provide an electrolytic processing method which can remove, for example, an extra portion of a metal such as copper, which has been used for embedding of interconnects in trenches, into a flat surface while enhancing the level difference elimination effect, and which can shorten the processing time.

In order to achieve the above object, the present invention provides an electrolytic processing apparatus comprising: a processing electrode for processing a workpiece; a feeding electrode for feeding electricity to the workpiece; a power source for applying a voltage between the processing electrode and the feeding electrode; a pressure tight container housing the processing electrode and the feeding electrode therein; and a high-pressure liquid supply system for supplying a high-pressure liquid into the pressure tight container.

FIG. 8 shows the principle of electrolytic processing using an ion exchanger. FIG. 8 shows the ionic state in the reaction system when an ion exchanger 12a mounted on a processing electrode 14 and an ion exchanger 12b mounted on a feeding electrode 16 are brought into contact with or close to the surface of a workpiece 10, while a voltage is applied from a power source 17 to between the processing electrode 14 and the feeding electrode 16, and a liquid 18, such as ultrapure water, is supplied from a fluid supply section 19 to between the processing electrode 14, the feeding electrode 16 and the workpiece 10.

When using a liquid, like ultrapure water, which itself has a large resistivity, it is preferred to bring the ion exchanger 12a into “contact” with the surface of the workpiece 10. This can lower the electric resistance, lower the voltage applied, and reduce the power consumption. Thus, the “contact” in a processing according to the present invention does not imply “press” for giving a physical energy (stress) to a workpiece as in CMP, for example.

Water molecules 20 in the liquid 18, such as ultrapure water, are dissociated by the ion exchangers 12a, 12b into hydroxide ions 22 and hydrogenions 24. The hydroxide ions 22 thus produced, for example, are carried, by the electric field between the workpiece 10 and the processing electrode 14 and by the flow of the liquid 18, to the surface of the workpiece 10 facing the processing electrode 14, whereby the density of the hydroxide ions 22 in the vicinity of the workpiece 10 is increased, and the hydroxide ions 22 are reacted with the atoms 10a of the workpiece 10. The reaction product 26 produced by reaction is dissolved in the liquid 18 such as ultrapure water, and removed from the workpiece 10 by the flow of the liquid 18 along the surface of the workpiece 10. Removal processing of the surface layer of the workpiece 10 is thus effected.

As will be appreciated from the above, this processing method is effected purely by the electrochemical interaction between the reactant ions and the workpiece. This method thus clearly differs in the processing principle from a processing as by CMP according to which processing is effected by the combination of a physical interaction between a polishing member and a workpiece, and a chemical interaction between a chemical species in a polishing liquid and the workpiece. According to this method, the portion of the workpiece 10 facing the processing electrode 14 is processed. Therefore, by moving the processing electrode 14, the workpiece 10 can be processed into a desired surface configuration.

Further, since the electrolytic processing apparatus according to the present invention performs removal processing of a workpiece solely by the dissolution reaction based on the electrochemical interaction, as distinct from a CMP apparatus which performs processing by the combination of the physical interaction between a polishing member and a workpiece, and the chemical interaction between a chemical species in a polishing liquid and the workpiece, the present electrolytic processing apparatus can perform removal processing of a material without impairing the properties of the material. Even when the material is of a low mechanical strength, such as the above-described low-k material, removal processing of the material can be effected without causing any physical interaction. Further, as compared to conventional electrolytic processing apparatuses, the apparatus of the present invention, because of the use as an electrolysis liquid a liquid having an electric conductivity of not more than 500 μS/cm, preferably pure water, more preferably ultrapure water, can remarkably reduce contamination of the surface of a workpiece with impurities and can facilitate disposal of waste liquid after the processing.

Upon the above-described electrolytic processing, pits, in general, have a tendency to increase their numbers with an increase in the processing time. It has been confirmed empirically that the larger the amount of gasses (bubbles) generated at a surface of a workpiece during electrolytic processing is, the larger is the number of pits. Thus, when using an aqueous electrolytic liquid, the number of pits increases with an increase in the amount of oxygen and hydrogen generated at the electrodes. Such pits are therefore also called gas pits.

According to the present invention, the dissolution capacity of a gas in a liquid increases in proportion to the liquid pressure, while the amount of gas bubbles generated is determined as the difference between the amount of gas generated and the amount of gas dissolved in the liquid. Accordingly, by carrying out electrolytic processing in the presence of a high-pressure liquid, the dissolution speed and the dissolution amount of a gas generated at the surfaces of an electrode and a workpiece can be increased and, therefore, the amount of gas bubbles generated at the gas generation sites can be decreased whereby the formation of pits can be decreased.

A contact member is preferably provided between the workpiece and at least one of the processing electrode and the feeding electrode.

Preferably, the apparatus further comprises an electrode section including the feeding electrode and the processing electrode and a contact member disposed between the electrode section and the workpiece and/or between the processing electrode and the feeding electrode of the electrode section.

The contact member comprises preferably an ion exchanger or a polishing pad.

By thus using the ion exchanger as the contact member, the electrolytic processing can be performed such that the dissociation into hydrogen ions and hydroxide ions of water molecules in the liquid, such as ultrapure water, is promoted.

In a preferred embodiment of the present invention, the pressure of the high-pressure liquid to be supplied into the pressure tight container is not lower than 2 kgf/cm².

It is preferred that the high-pressure liquid supply system be provided with a heat exchanger for adjusting a temperature of the high-pressure liquid to be supplied into the pressure tight container.

The dissolution speed and the dissolution capacity of a gas in a liquid decrease with an increase in the liquid temperature. Accordingly, by lowering the temperature of the high-pressure liquid to be supplied into the pressure tight container, the gas dissolution speed and the gas dissolution capacity in the liquid can be increased, whereby the amount of gas bubbles generated at the gas generation sites can be decreased and, at the same time, expansion of the gas due to the liquid temperature can be suppressed.

It is preferred that the high-pressure liquid supply system be provided with a degassing device for releasing a dissolved gas from the high-pressure liquid to be supplied into the pressure tight container.

When a dissolved gas is present in a liquid, the gas dissolution capacity decreases by the gas partial pressure corresponding to the amount of dissolved gas. Further, the gas dissolution speed decreases with an increase in the amount of gas existing in liquid, because the dissolution capacity of the remaining gas decreases. Accordingly, by previously releasing dissolved gas from the high-pressure liquid in advance of its supply into the pressure tight container, the gas dissolution capacity and the gas dissolution speed in the liquid can be increased, whereby the amount of gas bubbles generated at the gas generation sites can be decreased.

The present invention provides another electrolytic processing apparatus comprising: a processing electrode for processing a workpiece; a feeding electrode for feeding electricity to the workpiece; a power source for applying a voltage between the processing electrode and the feeding electrode; and a liquid supply system for supplying a liquid between the workpiece and at least one of the processing electrode and the feeding electrode; wherein the liquid supply system is provided with a heat exchanger for adjusting a temperature of the liquid to be supplied between the workpiece and at least one of the processing electrode and the feeding electrode.

The dissolution speed and the dissolution capacity of a gas in a liquid decrease with an increase in the liquid temperature. Accordingly, by lowering the temperature of the high-pressure liquid to be supplied between a workpiece and at least one the processing electrode and the feeding electrode, the gas dissolution speed and the gas dissolution capacity in the liquid can be increased, whereby the amount of gas bubbles generated at the gas generation sites can be decreased and, at the same time, expansion of the gas due to the liquid temperature can be suppressed.

In a preferred embodiment of the present invention, the heat exchanger adjusts the liquid to be supplied between the workpiece and the ion exchange so that a liquid temperature becomes not higher than 25° C. In general, the temperature of the liquid supplied between the workpiece and the ion exchanger is preferably not higher than 25° C.

The present invention provides still another electrolytic processing apparatus comprising: an electrode section including an electrode member comprised of an electrode and an ion exchanger covering a surface of the electrode; a holder for holding a workpiece and bringing the workpiece into contact with the ion exchanger of the electrode member; a liquid supply system for supplying a liquid between the ion exchanger and the workpiece held by the holder; a drive mechanism for causing relative movement between the electrode section and the workpiece; and a power source to be connected to the electrode of the electrode member of the electrode section; wherein a continuous contact time of the ion exchanger with a point in a processing surface of the workpiece is not more than 10 msec.

The continuous contact time of the ion exchanger with a point in the processing surface of the workpiece is generally not more than 10 msec, preferably not more than 5 msec, more preferably not more than 1.5 msec.

It is preferred that the ion exchanger covering the electrode be designed to make contact with the workpiece held by the holder with a contact width of 0.2 to 1.5 mm.

The dissolution amount of a gas in a liquid increases with the gas dissolution time and finally approximates the gas dissolution capacity. Thus, the longer the gas dissolution time, the larger is the gas dissolution amount in the liquid. By narrowing the contact width of the contact area between the ion exchanger, covering the electrode, and the workpiece held by the holder, the passing time (processing time) of the electrode over a processing point on the workpiece can be shortened. This shortens the gas generation time and lengthens the gas dissolution time, thereby increasing the gas dissolution amount and decreasing the amount of gas bubbles generated at the gas generation sites. The contact width is generally 0.2 to 1. 5 mm, preferably 0.2 to 1.2 mm, more preferably 0.2 to 1.0 mm.

The drive mechanism is preferably designed to cause relative movement between the electrode section and the workpiece relative at a relative speed of not lower than 0.2 m/sec.

In electrolytic processing, a gas generated dissolves in the liquid present between the electrode and the workpiece. Accordingly, by making the relative speed between the electrode and the workpiece larger to thereby make larger the volume or flow rate of the liquid between the electrode and the workpiece to be replaced with the relative movement between the electrode and the workpiece, the amount of gas bubbles generated at the gas generation sites can be decreased. The relative speed is generally not lower than 0.2 m/sec, preferably not lower than 0.5 m/sec, more preferably not lower than 0.7 m/sec.

The present invention provides still another electrolytic processing apparatus comprising: an electrode section including an electrode member comprised of an electrode and an ion exchanger covering a surface of the electrode; a holder for holding a workpiece and bringing the workpiece into contact with the ion exchanger of the electrode member; a liquid supply system for supplying a liquid between the ion exchanger and the workpiece held by the holder; a drive mechanism for causing relative movement between the electrode section and the workpiece; and a power source to be connected to the electrode of the electrode member of the electrode section; wherein an on/off or positive/negative control of the power source is performed in synchronization with the relative movement between the electrode section and the workpiece.

By thus synchronizing the relative movement between the electrode section and the workpiece with the on/off control of the power source so that processing is carried out only within intervals during which the relative speed between the electrode of the electrode section and the workpiece in the width direction of the electrode is fast, for example, not lower than 0.2 m/sec, the amount of gas bubbles generated at the gas generation sites can be decreased as in the above-described case of increasing the relative speed.

It is preferred that the on/off control be performed such that the power source is on when the relative speed between the electrode of the electrode section and the workpiece in the width direction of the electrode section is not lower than 0.2 m/sec.

In a preferred embodiment of the present invention, adjacent electrode members are connected alternately to the cathode and to the anode of the power source.

The liquid is, for example, pure water, ultrapure water, or a liquid having an electric conductivity of not more than 500 μs/cm.

The present invention also provides an electrolytic processing method comprising: processing a workpiece in the presence of a high-pressure liquid by applying a voltage to an electrode section.

Preferably, the high-pressure liquid is supplied between the electrode section and the workpiece.

It is preferred that the workpiece be processed by immersing the workpiece and the electrode section in the high-pressure liquid.

Preferably, the electrode section includes a processing electrode for processing the workpiece and a feeding electrode for feeding electricity to the workpiece.

A pressure of the high-pressure liquid is preferably not lower than 2 kgf/cm².

The present invention provides another electrolytic processing method comprising: processing a workpiece in the presence of a high-pressure liquid by applying a voltage to an electrode section; wherein the electrode section includes a processing electrode for processing the workpiece and a feeding electrode for feeding electricity to the workpiece.

The present invention provides still another electrolytic processing method comprising: providing a processing electrode which can come close to or into contact with a workpiece, and a feeding electrode for feeding electricity to the workpiece; and processing the workpiece by applying a voltage between the processing electrode and the feeding electrode while supplying a liquid at an adjusted temperature between the workpiece and at least one of the processing electrode and the feeding electrode.

The present invention provides still another electrolytic processing method comprising: providing a processing electrode which can come close to or into contact with a workpiece, and a feeding electrode for feeding electricity to the workpiece; and processing the workpiece by applying a voltage between the processing electrode and the feeding electrode while supplying a degassed liquid between the workpiece and at least one of the processing electrode and the feeding electrode.

It is preferred that an ion exchanger be provided between the workpiece and at least one of the processing electrode and the feeding electrode.

The present invention provides still another electrolytic processing method comprising: processing a workpiece in the presence of a liquid by applying a voltage to an electrode and moving an ion exchanger, covering a surface of the electrode, and the workpiece held by a holder relative to each other, while keeping the ion exchanger and the workpiece in contact with each other, such that the contact time of the ion exchanger with a point in a processing surface of the workpiece is not more than 10 msec.

It is preferred that the ion exchanger and the workpiece held by the holder contact each other with a contact width of 0.2 to 1.5 mm.

It is preferred that the ion exchanger and the workpiece held by the holder are moved relative to each other at a relative speed of not less than 0.2 m/sec while keeping them in linear contact with each other.

The present invention provides still another electrolytic processing method comprising: processing a workpiece in the presence of a liquid by applying a voltage to a plurality of electrodes arranged in parallel and moving an ion exchanger, covering the surfaces of the plurality of electrodes, and the workpiece held by a holder relative to each other while keeping the ion exchanger and the workpiece in contact with each other; wherein the voltage is on/off or positive/negative controlled in synchronization with the relative movement.

The present invention provides still another electrolytic processing method comprising: bringing a workpiece and a processing electrode close to or into contact with each other; and processing the workpiece in the presence of a liquid by applying a voltage between the workpiece and the processing electrode while moving the workpiece and the processing electrode relative to each other; wherein the relative speed between the workpiece and the processing electrode is made fast in an initial processing stage and slow in a later processing stage.

According to this method, in the initial processing stage, the effect of eliminating a level difference can be enhanced by using a high relative speed between the workpiece and the processing electrode, while in the later stage when the level difference has been eliminated, the processing rate can be increased by lowering the relative speed between the workpiece and the processing electrode. This manner of processing can thus attain enhancement of the level difference elimination effect and shortening of the processing time.

In a preferred embodiment of the present invention, the relative speed between the workpiece and the processing electrode is made slow when the thickness of a film, which is formed in a processing surface of the workpiece and is being processed, has reached a value of not more than 600 nm.

The timing of making the relative speed between the workpiece and the processing electrode slow is when the thickness of the film has a reached a value of generally not more than 600 nm, preferably not more than 500 nm, and more preferably not more than 400 nm.

The present invention provides still another electrolytic processing method comprising: bringing a workpiece and a processing electrode close to or into contact with each other; and processing the workpiece in the presence of a liquid by applying a voltage between the workpiece and the processing electrode while moving the workpiece and the processing electrode relative to each other; wherein the relative speed between the workpiece and the processing electrode is made fast in an initial processing stage, slow in an intermediate processing stage, and faster in a later processing stage than the intermediate processing stage.

According to this method, the relative speed between the workpiece and the processing electrode is made fast in the initial processing stage to enhance the effect of eliminating a level difference, and the relative speed is made slow in the intermediate processing stage, thereby increasing the processing rate. Further, the relative speed between the workpiece and the processing electrode is made again fast in the later processing stage to enhance the level difference elimination effect and carry out finish processing while preventing the formation of pits in the processing surface. Further, by lowering the processing rate in the later processing stage, the end point of processing can be detected more precisely.

In a preferred embodiment of the present invention, the relative speed between the workpiece and the processing electrode is made slow when the thickness of the film being processed has reached a value of not more than 600 nm, and the relative speed between the workpiece and the processing electrode is made again fast when the thickness of the film has reached a value of 50 to 300 nm.

The timing of making the relative speed between the workpiece and the processing electrode slow in the intermediate processing stage is when the thickness of the film has reached a value of generally not more than 600 nm, preferably not more than 500 nm, and more preferably not more than 400 nm. The timing of making the relative speed between the workpiece and the processing electrode again fast in the later processing stage is when the thickness of the film has reached a value of generally 50 to 300 nm, preferably 50 to 200 nm, more preferably 50 to 120 nm.

The present invention also provides still another electrolytic processing method comprising: bringing a workpiece and a processing electrode close to or into contact with each other; and processing the workpiece in the presence of a liquid by applying a voltage between the workpiece and the processing electrode while moving the workpiece and the processing electrode relative to each other; wherein the relative speed between the workpiece and the processing electrode is made slow in an initial processing stage and fast in a later processing stage.

According to this method, the relative speed between the workpiece and the processing electrode is made slow in the initial processing stage to increase the processing rate, and the relative speed is made fast in the later processing stage, thereby enhancing the level difference elimination effect. This manner of processing can thus attain enhancement of the level difference elimination effect and shortening of the processing time.

In a preferred embodiment of the present invention, the relative speed between the workpiece and the processing electrode is made fast when the thickness of the film being processed has reached a value of 50 to 300 nm.

The timing of making the relative speed between the workpiece and the processing electrode fast in the later processing stage is when the thickness of the film has reached a value of generally 50 to 300 nm, preferably 50 to 200 nm, and more preferably 50 to 150 nm.

The relative speed between the workpiece and the processing electrode may be changed stepwise. Alternatively, the relative speed between the workpiece and the processing electrode may be changed continuously, for example, linearly or in a curve.

The present invention also provides still another electrolytic processing method comprising: bringing a workpiece and a processing electrode close to or into contact with each other; and processing the workpiece in the presence of a liquid by applying a voltage between the workpiece and the processing electrode while causing relative movement between the workpiece and the processing electrode by allowing the workpiece and/or the processing electrode to make a cyclic movement; wherein the cycle of the cyclic movement of the workpiece and/or the processing electrode is changed during processing.

According to the present invention, unlike a CMP processing, electrolytic processing of a workpiece, such as a substrate, can be effected through an electrochemical action without causing any physical defects in the workpiece that would impair the properties of the workpiece. Further, the present electrolytic processing apparatus and method can effectively remove (clean) matter adhering to the surface of the workpiece. Accordingly, the present invention can omit a CMP processing entirely or at least reduce a load upon CMP. Further, the electrolytic processing of a substrate can be effected even by solely using pure water or ultrapure water. This prevents impurities such as an electrolyte from adhering to and remaining on the surface of the substrate, can simplify a cleaning process after the removal processing, and can remarkably reduce a load upon waste liquid disposal.

According to the present invention, the effect of eliminating a level difference can be enhanced by making the relative speed between a workpiece and a processing electrode fast during processing, while the processing rate can be increased by making the relative speed between the workpiece and the processing electrode slow. This manner of processing can thus enhance the level difference elimination effect and shorten the processing time. Further, the formation of pits in the processing surface, which would impair the quality of the workpiece, can be prevented.

### BRIEF DESCRIPTION OF DRAWINGS

FIGS. 1A through 1C are diagrams illustrating, in sequence of process steps, an example of the production of a substrate with copper interconnects;

FIG. 2 is a graph showing the relationship between the “relative speed” between a workpiece and a processing electrode and “processing rate”;

FIG. 3A is a diagram illustrating a hydroplaning phenomenon as observed when the relative speed between a workpiece and a processing electrode is slow, and FIG. 3B is a diagram illustrating a hydroplaning phenomenon as observed when the relative speed is fast;

FIG. 4A is a diagram illustrating the concentration of processing products when the relative speed between a workpiece and a processing electrode is slow, and FIG. 4B is a diagram illustrating the concentration of processing products when the relative speed is fast;

FIG. 5 is a graph showing the relationship between “processing amount” and “level difference”;

FIG. 6A is a diagram illustrating the concentration of processing products when the relative speed between a workpiece and a processing electrode is slow, and FIG. 6B is a diagram illustrating the concentration of processing products when the relative speed is fast;

FIG. 7A is a diagram illustrating the deformation of an ion exchanger when the relative speed between a workpiece and a processing electrode is slow, and FIG. 7B is a diagram illustrating the deformation of an ion exchanger when the relative speed is fast;

FIG. 8 is a diagram illustrating the principle of electrolytic processing according to the present invention as carried out by bringing a processing electrode and a feeding electrode closed to a substrate (workpiece), and supplying pure water or a fluid having an electric conductivity of not more than 500 μS/cm between the processing electrode, the feeding electrode and the substrate (workpiece);

FIG. 9 is a schematic view of an electrolytic processing apparatus according to an embodiment of the present invention;

FIG. 10 is a graph showing the relationship between “gas dissolution speed & gas dissolution amount” and “water pressure”;

FIG. 11 is a graph showing the relationship between “gas dissolution amount” and “liquid temperature”;

FIG. 12 is a graph showing the relationship between “gas dissolution capacity” and “water pressure” with respect to liquids with different initial amounts of dissolved gas;

FIG. 13 is a graph showing the relationship between “gas dissolution speed” and “amount of gas existing in liquid”;

FIG. 14 is a plan view showing the construction of a substrate processing apparatus provided with an electrolytic processing apparatus according to another embodiment of the present invention;

FIG. 15 is a plan view of the electrolytic processing apparatus of the substrate processing apparatus shown in FIG. 14;

FIG. 16 is a vertical sectional view of FIG. 15;

FIG. 17A is a plan view of the rotation preventing mechanism of the electrolytic processing apparatus of FIG. 15, and FIG. 17B is a sectional view taken along the line A-A of FIG. 17A;

FIG. 18 is a plan view of the electrode section of the electrolytic processing apparatus of FIG. 15;

FIG. 19 is a sectional view taken along the line B-B of FIG. 18;

FIG. 20 is an enlarged view of a portion of FIG. 19;

FIG. 21A is a graph showing the relationship between “electric current” and “time”, as observed in electrolytic processing of the surface of a substrate having a film of two different materials formed in the surface, and FIG. 21B is a graph showing the relationship between “voltage” and “time”, as observed in electrolytic processing of the surface of a substrate having a film of two different materials formed in the surface;

FIG. 22 is a cross-sectional diagram illustrating the state of contact between an ion exchanger and a substrate during electrolytic processing;

FIGS. 23A through 23C are diagrams illustrating the mechanism of eliminating a variation in processing amount by moving a substrate holder for a predetermined distance in Y direction, in addition to scroll movement of an electrode section, during electrolytic processing;

FIGS. 24A through 24D are diagrams illustrating an electrolytic processing method which can eliminate a variation in processing amount by moving a substrate holder for a predetermined distance in Y direction, in addition to scroll movement of an electrode section, during electrolytic processing;

FIG. 25 is a graph showing the relationship between “gas dissolution amount” and “gas dissolution time”;

FIG. 26 is a graph showing the relationship between “gas dissolution speed & gas dissolution amount” and “water pressure” with respect to liquids with different volumes;

FIG. 27 is a graph showing the relationship between “number of pits” and “relative speed” in electrolytic processing carried out by using electrodes 1 to 4 with different contact widths;

FIG. 28 is a graph showing the relationship between “number of pits” and “electrode (ion exchanger) contact time” in electrolytic processing carried out by using electrodes 1 to 4 with different contact widths;

FIGS. 29A through 29C are diagrams illustrating the relative speed between an electrode and a point in a surface of a substrate in relative scroll movement between an electrode section and a substrate;

FIG. 30 is a diagram illustrating an on/off control of a power source in synchronization with the relative scroll movement;

FIG. 31 is a plan view showing the construction of a substrate processing apparatus provided with an electrolytic processing apparatus for carrying out an electrolytic processing method according to the present invention;

FIG. 32 is a vertical sectional view of the electrolytic processing apparatus of the substrate processing apparatus shown in FIG. 31;

FIG. 33 is a graph showing an example of the relationship between the “relative speed” between a workpiece (substrate) and a processing electrode (electrode) and “processing time” in an electrolytic processing method according to the present invention;

FIG. 34 is a graph showing another example of the relationship between the “relative speed” between a workpiece (substrate) and a processing electrode (electrode) and “processing time” in an electrolytic processing method according to the present invention;

FIG. 35 is a graph showing still another example of the relationship between the “relative speed” between a workpiece (substrate) and a processing electrode (electrode) and “processing time” in an electrolytic processing method according to the present invention;

FIG. 36 is a graph showing still another example of the relationship between the “relative speed” between a workpiece (substrate) and a processing electrode (electrode) and “processing time” in an electrolytic processing method according to the present invention;

FIG. 37 is a graph showing still another example of the relationship between the “relative speed” between a workpiece (substrate) and a processing electrode (electrode) and “processing time” in an electrolytic processing method according to the present invention;

FIG. 38 is a vertical sectional view of the main portion of another electrolytic processing apparatus suited for carrying out an electrolytic processing method according to the present invention;

FIG. 39 is an enlarged view of the main portion of FIG. 38; and

FIG. 40 is a plan view schematically showing still another electrolytic processing apparatus suited for carrying out an electrolytic processing method according to the present invention.

### BEST MODE FOR CARRYING OUT THE INVENTION

Preferred embodiments of the present invention will now be described in detail with reference to the drawings. Though the following description illustrates the case of processing a substrate as a workpiece by an electrolytic processing apparatus, the present invention is of course applicable to workpieces other than a substrate.

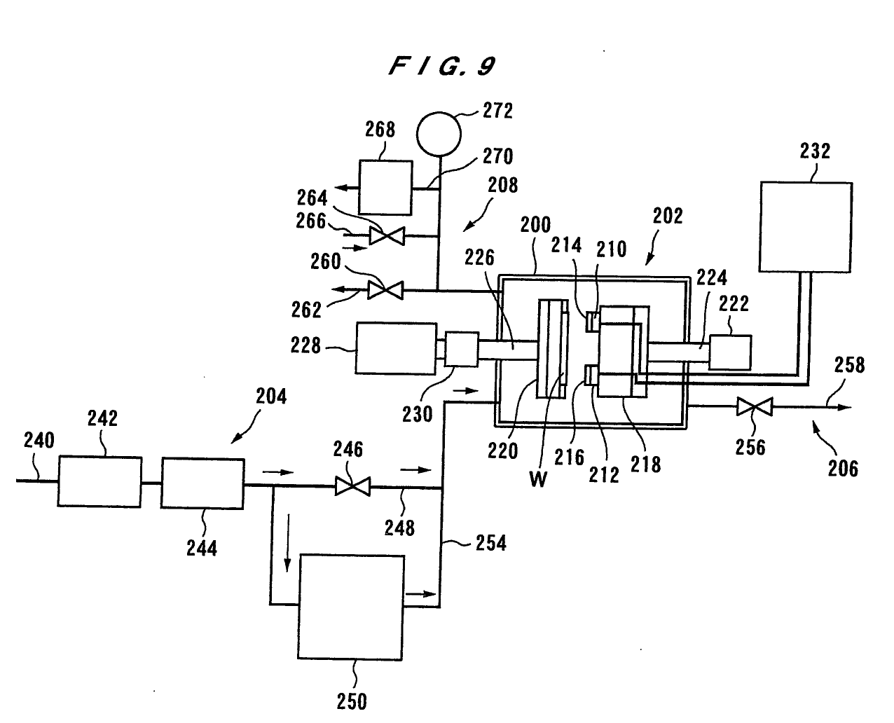

FIG. 9 shows a schematic view of an electrolytic processing apparatus according to a first embodiment of the present invention. The electrolytic processing apparatus is mainly comprised of a main apparatus 202 having a hermetically closable pressure tight container 200, a high-pressure liquid supply system 204 for supplying a high-pressure liquid to the pressure tight container 200 of the main apparatus 202, a liquid discharge system 206 for discharging a liquid in the pressure tight container 200 to the outside, and an auxiliary line system 208.

The main apparatus 202 includes an electrode plate 218 having a pair of a processing electrode 210 and a feeding electrode 212, whose exposed surfaces are respectively covered with ion exchangers 214, 216, and a substrate holder 220 for detachably holding a substrate W, such as a semiconductor wafer. The electrode plate 218 and the substrate holder 220 are disposed opposite to each other in the pressure tight container 200. The electrode plate 218 is fixed to the front end of a main shaft 224 which penetrates the pressure tight container 200 and is movable back and forth by a drive section 222. The substrate holder 220, on the other hand, is fixed to the front end of a rotating shaft 226 which penetrates the pressure tight container 200 and is coupled via a coupling 230 to the output shaft of a motor 228.

The ion exchangers 214, 216 may be composed of a non-woven fabric which has an anion-exchange group or a cation-exchange group. A cation exchanger preferably carries a strongly acidic cation-exchange group (sulfonic acid group); however, a cation exchanger carrying a weakly acidic cation-exchange group (carboxyl group) may also be used. Though an anion exchanger preferably carries a strongly basic anion-exchange group (quaternary ammonium group), an anion exchanger carrying a weakly basic anion-exchange group (tertiary or lower amino group) may also be used.

The non-woven fabric carrying a strongly basic anion-exchange group can be prepared by, for example, the following method: A polyolefin non-woven fabric having a fiber diameter of 20-50 μm and a porosity of about 90% is subjected to the so-called radiation graft polymerization, comprising γ-ray irradiation onto the non-woven fabric and the subsequent graft polymerization, thereby introducing graft chains; and the graft chains thus introduced are then aminated to introduce quaternary ammonium groups thereinto. The capacity of the ion-exchange groups introduced can be determined by the amount of the graft chains introduced. The graft polymerization may be conducted by the use of a monomer such as acrylic acid, styrene, glicidyl methacrylate, sodium styrenesulfonate or chloromethylstyrene, or the like. The amount of the graft chains can be controlled by adjusting the monomer concentration, the reaction temperature and the reaction time. Thus, the degree of grafting, i.e. the ratio of the weight of the non-woven fabric after graft polymerization to the weight of the non-woven fabric before graft polymerization, can be made 500% at its maximum. Consequently, the capacity of the ion-exchange groups introduced after graft polymerization can be made 5 meq/g at its maximum.

The non-woven fabric carrying a strongly acidic cation-exchange group can be prepared by the following method: As in the case of the non-woven fabric carrying a strongly basic anion-exchange group, a polyolefin non-woven fabric having a fiber diameter of 20-50 μm and a porosity of about 90% is subjected to the so-called radiation graft polymerization comprising γ-ray irradiation onto the non-woven fabric and the subsequent graft polymerization, thereby introducing graft chains; and the graft chains thus introduced are then treated with a heated sulfuric acid to introduce sulfonic acid groups thereinto. If the graft chains are treated with a heated phosphoric acid, phosphate groups can be introduced. The degree of grafting can reach 500% at its maximum, and the capacity of the ion-exchange groups thus introduced after graft polymerization can reach 5 meq/g at its maximum.

The base material of the ion exchangers 214, 216 may be a polyolefin such as polyethylene or polypropylene, or any other organic polymer. Further, besides the form of a non-woven fabric, the ion exchanger may be in the form of a woven fabric, a sheet, a porous material, or short fibers, etc.

When polyethylene or polypropylene is used as the base material, graft polymerization can be effected by first irradiating radioactive rays (γ-rays and electron beam) onto the base material (pre-irradiation) to thereby generate a radical, and then reacting the radical with a monomer, whereby uniform graft chains with few impurities can be obtained. When an organic polymer other than polyolefin is used as the base material, on the other hand, radical polymerization can be effected by impregnating the base material with a monomer and irradiating radioactive rays (γ-rays, electron beam and UV-rays) onto the base material (simultaneous irradiation). Though this method fails to provide uniform graft chains, it is applicable to a wide variety of base materials.

By using a non-woven fabric having an anion-exchange group or a cation-exchange group as the ion exchangers 214, 216, it becomes possible that pure water or ultrapure water, or a liquid such as an electrolytic solution can freely move within the non-woven fabric and easily arrive at the active points in the non-woven fabric having a catalytic activity for water dissociation, so that many water molecules are dissociated into hydrogen ions and hydroxide ions. Further, by the movement of pure water or ultrapure water, or a liquid such as an electrolytic solution, the hydroxide ions produced by the water dissociation can be efficiently carried to the surfaces of the processing electrodes, whereby a high electric current can be obtained even with a low voltage applied.

When the ion exchangers 214, 216 have only one of anion-exchange groups and cation-exchange groups, a limitation is imposed on electrolytically processible materials and, in addition, impurities are likely to form due to the polarity. In order to solve this problem, an anion exchanger carrying an anion-exchange group and a cation exchanger carrying a cation-exchange group may be superimposed, or the ion exchangers 214, 216 may carry both of an anion-exchange group and a cation-exchange group per se, whereby a range of materials to be processed can be broadened and the formation of impurities can be restrained.

This invention is not limited to electrolytic processing using an ion exchanger. When using, for example, an electrolytic solution as a processing liquid, a processing member (contact member) to be mounted on the surfaces of the electrodes is not limited to ion exchangers 214,216 which are the most suitable for pure water or ultrapure water, but a soft polishing pad or a non-woven fabric, or the like may also be used. Politex (trademark of Rodel Products Corporation), a polyurethane sponge, a non-woven fabric, a foamed polyurethane or a PVD sponge may be used as a contact member.

According to this embodiment, the processing electrode 210 is connected to the cathode of a power source 232, and the feeding electrode 212 is connected to the anode of the power source 232. This is because electrolytic processing of e.g. copper proceeds on the cathode side. Depending upon the material to be processed, the electrode connected to the cathode of the power source 232 may serve as a feeding electrode, and the electrode connected to the anode may serve as a processing electrode. Thus, when the material to be processed is copper, molybdenum, iron, or the like, the electrolytic processing action occurs on the cathode side, and therefore the electrode connected to the cathode of the power source 232 becomes a processing electrode 210, and the electrode connected to the anode becomes a feeding electrode 212. On the other hand, when the material to be processed is aluminum, silicon, or the like, the electrolytic processing action occurs on the anode side, and therefore the electrode connected to the anode of the power source 232 becomes a processing electrode and the electrode connected to the cathode becomes a feeding electrode.

With respect to the processing electrodes 210 and the feeding electrodes 212, oxidation or dissolution thereof due to an electrolytic reaction may be a problem. In view of this, as a material for the electrode, it is possible to use, besides the conventional metals and metal compounds, carbon, relatively inactive noble metals, conductive oxides or conductive ceramics. A noble metal-based electrode may, for example, be one obtained by plating or coating platinum or iridium onto a titanium that is used as an electrode base material, and then sintering the coated electrode at a high temperature to stabilize and strengthen the electrode. Ceramics products are generally obtained by heat-treating inorganic raw materials, and ceramics products having various properties are produced from various raw materials including oxides, carbides and nitrides of metals and nonmetals. Among them there are ceramics having an electric conductivity. When an electrode is oxidized, the value of the electric resistance generally increases to cause an increase of applied voltage. However, by protecting the surface of an electrode with a non-oxidative material such as platinum or with a conductive oxide such as an iridium oxide, the decrease of electric conductivity due to oxidation of the base material of an electrode can be prevented.

The high-pressure liquid supply system 204 includes a pure water line 240 for transporting pure water, preferably ultrapure water. In the pure water line 240 is provided a heat exchanger 242 for adjusting the temperature of pure water flowing along the pure water line 240, and a degassing device 244 for releasing dissolved gas from pure water flowing along the pure water line 240. On the downstream side of the degassing device 244, the pure water line 240 branches into an initial water supply line 248 having a shut-off valve 246 interposed therein, and a high-pressure pure water supply line 254 having a high-pressure (ultra) pure water production device 250 interposed therein, and the two lines meet again and the unified line is connected to the pressure tight container 200 of the main apparatus 202.

Pure water flowing through the pure water line 240 is first passed through the heat exchanger 242, where pure water is cooled so that its temperature becomes not higher than 25° C. Pure water is then passed through the degassing device 244 to remove (release) initial dissolved gas. Initially, the shut-off valve 246 is opened to pass the cooled and degassed pure water through the initial water supply line 248 and supply the pure water into the pressure tight container 200. When carrying out electrolytic processing, on the other hand, the shut-off valve 246 is closed to pass pure water through the high-pressure pure water supply line 254. Pure water is pressurized to a pressure of not less than 2 kgf/cm² in the high-pressure pure water production device 250, and the pressurized pure water is supplied into the pressure tight container 200.

According to this embodiment, a plunger pump is used as the high-pressure pure water production device 250, and pure water which has been pressurized by the high-pressure pure water production device (plunger pump) 250 is supplied into the pressure tight container 200 so as to pressurize pure water, which has been stored in the pressure tight container 200, to a predetermined pressure.

The liquid discharge system 206 includes a water discharge line 258 having a shut-off valve 258 interposed therein. The liquid in the pressure tight container 200 can be discharged/shut off by opening/closing the shut-off valve 256.

The auxiliary line system 208 includes an auxiliary line 262, for water discharge and degassing, which has a shut-off valve 260 interposed therein and which is connected to the pressure tight container 200. To the auxiliary line 262 are connected an inert gas supply line 266 having a shut-off valve 264 interposed therein, and a safety line 270 provided with a relief valve 268 that opens at a lower pressure than the limit pressure of the pressure tight container 200. The auxiliary line system 208 is also provided with a pressure gauge 272 for detecting the pressure of the liquid (pressurized pure water) in the pressure tight container 200.

By opening the shut-off valve 264 of the inert gas supply line 266, an inert gas such as N₂ gas can be supplied into the pressure tight container 200. Further, with the provision of the safety line 270 having the relief valve 268 that opens at a lower pressure than the limit pressure of the pressure tight container 200, the pressure of the liquid (pure water) in the pressure tight container 200 can be released before the pressure reaches the limit pressure of the pressure tight container 200, whereby the pressure tight container 200 can be prevented from being destroyed by the liquid pressure.

Pure water herein refers to a water having an electric conductivity of not more than 10 μS/cm (referring herein to that at 25° C., 1 atm), and ultrapure water refers to a water having an electric conductivity of not more than 0.1 μS/cm. The use of pure water or ultrapure water containing no electrolyte upon electrolytic processing can prevent extra impurities such as an electrolyte from adhering to and remaining on the surface of the substrate W.

It is possible to use, instead of pure water or ultrapure water, a liquid having an electric conductivity of not more than 500 μS/cm or an electrolytic solution obtained by adding an electrolyte to pure water or ultrapure water. The use of an electrolytic solution can further lower the electric resistance and reduce the power consumption. A solution of a neutral salt such as NaCl or Na₂SO₄, a solution of an acid such as HCl or H₂SO₄, or a solution of an alkali such as ammonia, may be used as the electrolytic solution, and these solutions may be selectively used according to the properties of the workpiece.

Further, it is also possible to use, instead of pure water or ultrapure water, a liquid obtained by adding a surfactant to pure water or ultrapure water, and having an electric conductivity of not more than 500 μS/cm, preferably not more than 50 μS/cm, more preferably not more than 0.1 μS/cm. Due to the presence of a surfactant, the liquid can form a layer, which functions to inhibit ion migration evenly, at the interface between the substrate W and the ion exchangers 214, 216, thereby moderating concentration of ion exchange (metal dissolution) to enhance the flatness of the processed surface. The surfactant concentration is desirably not more than 100 ppm. When the value of the electric conductivity is too high, the current efficiency is lowered and the processing rate is decreased. The use of the liquid having an electric conductivity of not more than 500 μS/cm, preferably not more than 50 μS/cm, more preferably not more than 0.1 μS/cm, can attain a desired processing rate.

An example of electrolytic processing carried out by the electrolytic processing apparatus of this embodiment will now be described.

First, a substrate W is held by the substrate holder 220. At this moment, the pressure tight container 200 is vacant, and the electrode plate 218 is in an opposite position to the substrate W held by the substrate holder 220 at a predetermined distance.

Then, the shut-off valve 264 of the inert gas supply line 266 is opened to supply an inert gas, such as N₂ gas, into the pressure tight container 200, thereby replacing the internal atmosphere of the pressure tight container 200 with the inert gas, such as N₂ gas. By the replacement with the inert gas, such as N₂ gas, gasses present in the pressure tight container 200, such as O₂, which will also be generated during electrolytic processing and are intended to be dissolved in the liquid (pure water) used in the electrolytic processing, are forced out and removed in advance of the electrolytic processing. In particular, O₂ gas is present in plenty in the air, and therefore should desirably be removed in advance.

Next, the shut-off valve 246 of the initial water supply line 248 is opened to supply pure water, which has been cooled (temperature-adjusted) by the heat exchanger 242 and degassed by the degassing device 244, through the initial water supply line 248 into the pressure tight container 200 and, at the same time, the shut-off valve 260 of the auxiliary line 262 is opened, thereby filling the pressure tight container 200 with un-pressurized pure water while discharging gasses and gas bubbles remaining in the pressure tight container 200 to the outside.

Thereafter, the shut-off valve 246 of the initial water supply line 248 is closed to supply high-pressure pure water, which has been produced in the high-pressure pure water production device 250, through the high-pressure pure water line 254 into the pressure tight container 200, thereby filling the pressure tight container 200 with pure water pressurized at, for example, 2 kgf/cm². According to this embodiment, as described above, a plunger pump is used as the high-pressure pure water production device 250, and un-pressurized pure water filling the pressure tight container 200 is pressurized by pure water discharged from the plunger pump. This, however, is of course not limitative of the present invention.

Electrolytic processing is initiated when the pressure tight container 200 is thus filled with high-pressure pure water.

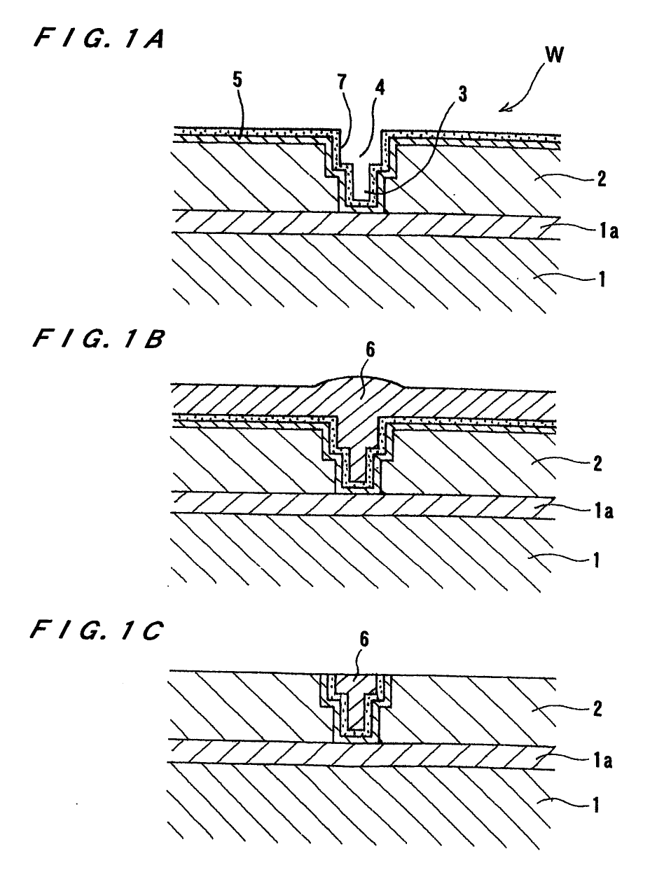

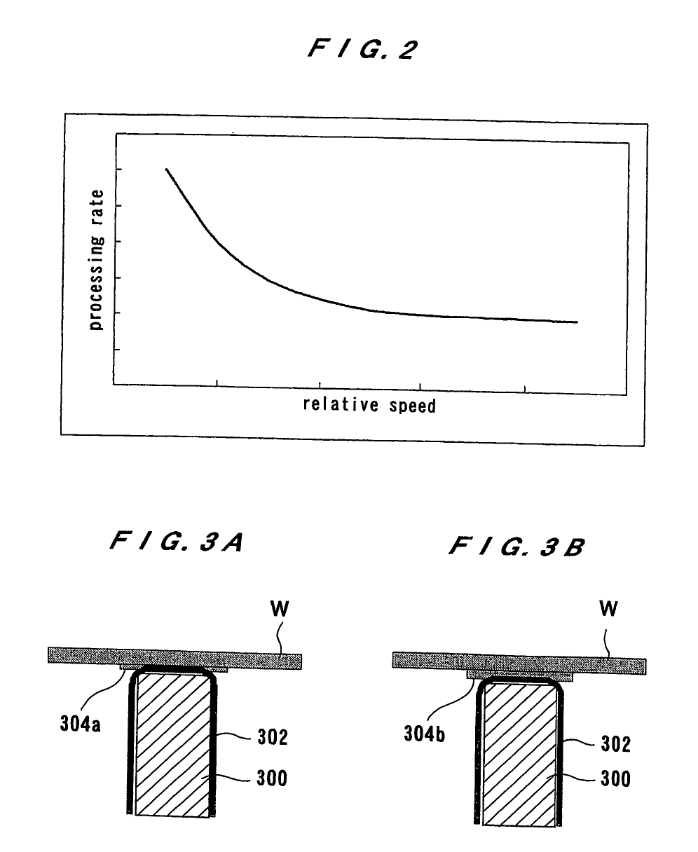

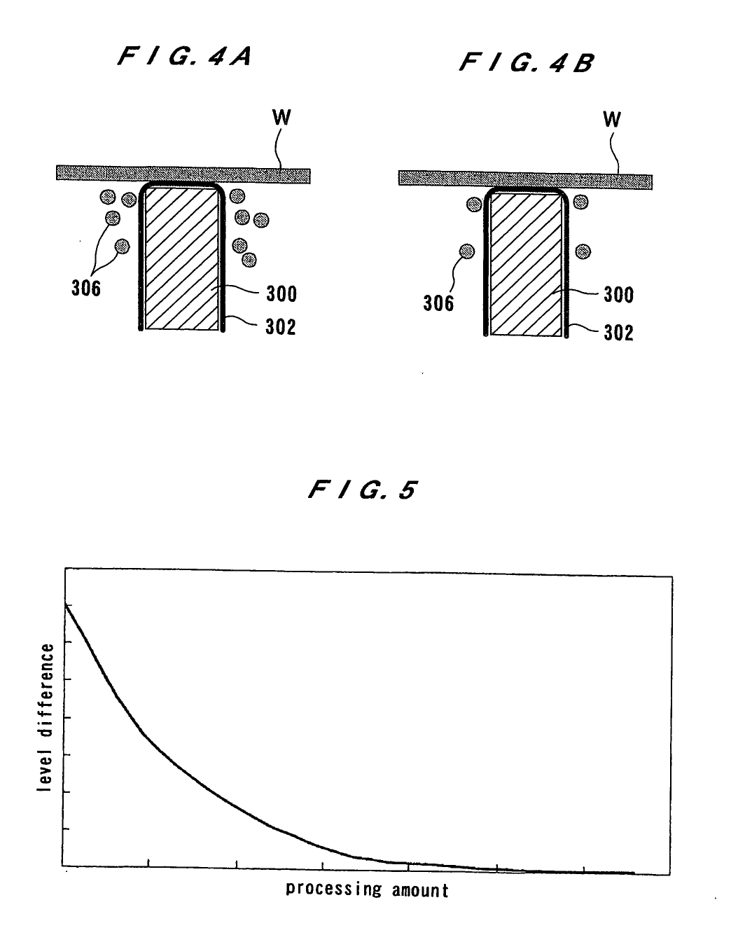

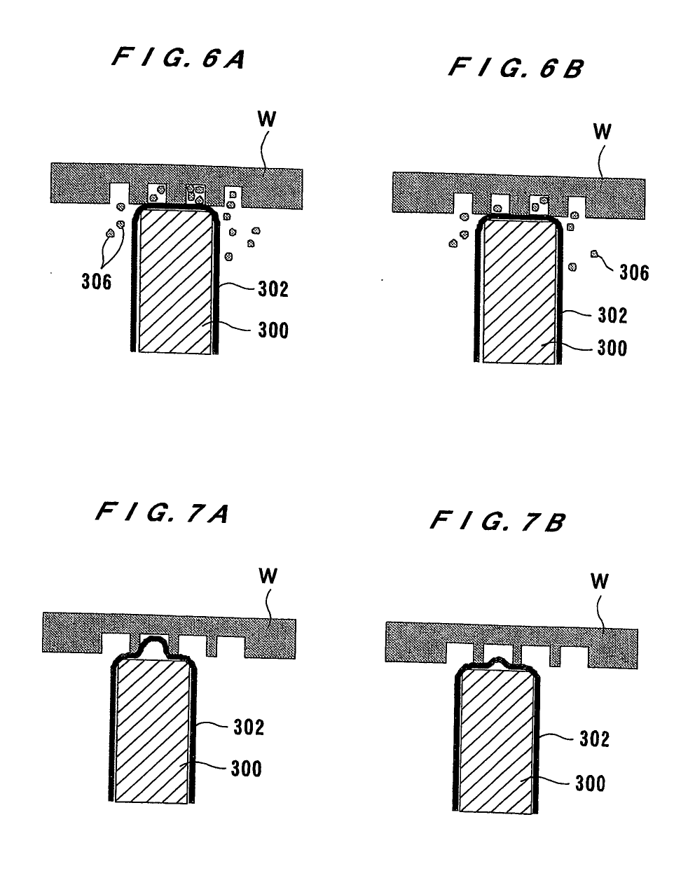

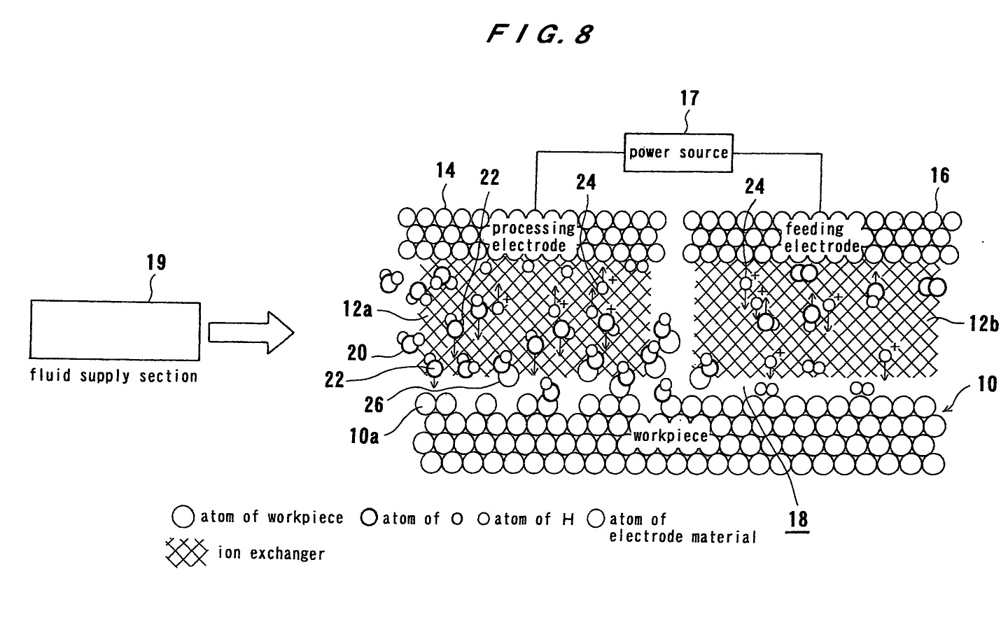

First, the drive section 222 is driven to move the electrode plate 218 forward to the substrate W held by the substrate holder 220 so as to bring the ion exchangers 214, 216 into contact with the substrate W. The motor 228 is then driven to rotate the substrate W together with the substrate holder 220. A predetermined voltage is applied from the power source 232 to between the processing electrode 210 and the feeding electrode 212 to carry out electrolytic processing of a conductive film on the substrate W, for example, a copper film 6 shown in FIG. 1B, through the action of hydrogen ions or hydroxide ions generated by the ion exchangers 214, 216, at the processing electrode (cathode) 210.

During electrolytic processing, the voltage applied between the processing electrode 210 and the feeding electrode 212 or an electric current flowing therebetween is monitored with a monitor section to detect the end point of processing.

When using a liquid, like ultrapure water, which itself has a large resistivity, it is preferred to bring the ion exchangers 214, 216 into contact with the substrate W. This can lower the electric resistance, lower the voltage applied and reduce the power consumption. The “contact” does not imply “press” for giving a physical energy (stress) to a workpiece as in CMP. In this regard, according to CMP, a substrate is pressed against a polishing surface generally at a pressure of about 20 to 50 kPa. According to the electrolytic processing apparatus of this embodiment, on the other hand, the ion exchangers 214, 216 may be in contact with the substrate W at a pressure of not more than 20 kPa, for example. A sufficient processing effect will be produced even with a pressure of not more than 10 kPa.

After completion of the electrolytic processing, the processing electrode 210 and the feeding electrode 212 are disconnected from the power source 232, and the rotation of the substrate holder 220 is stopped, and then the electrode plate 218 is moved away from the substrate holder 220.

Thereafter, the shut-off valve 260 of the auxiliary line 262 is first opened to depressurize the high-pressure pure water in the pressure tight container 200. Thus, part of pure water and a gas, which has collected thereon, are discharged out of the pressure tight container 200. Simultaneously with the depressurization, the shut-off valve 264 of the inert gas supply line 266 is opened to supply an inert gas, such as N₂ gas, into the pressure tight container 200. H₂, which has been dissolved in the high-pressure pure water, and has gasified and thus rapidly increased its volume, is diluted with the inert gas, such as N₂ gas. This prevents explosion of H₂.

Next, the shut-off valve 256 of the water discharge line 258 is opened to discharge the pure water in the pressure tight container 200 through the water discharge line to the outside, thereby completing the electrolytic processing operations.

According to this embodiment, the electrolytic processing is thus carried out while filling the pressure tight container 200 with high-pressure pure water at a pressure of e.g. not lower than 2 kgf/cm², pure water (high-pressure pure water) at a low temperature of e.g. not higher than 25° C. is supplied into the pressure tight container 200, and the pure water (high-pressure pure water) supplied into the pressure tight container 200 has previously been degassed to release dissolved gas. This can prevent formation of pits in the processed surface of a conductive film, for example, the copper film 6 shown in FIG. 1B, on a substrate W. The mechanism of the prevention of pit formation will now be explained.

The amount of gas bubbles generated, which are the cause of the formation of pits, can be determined as the difference between the amount of gas generated and the amount of gas dissolved in pure water (liquid), i.e.,
Amount of gas bubbles=amount of generated gas−amount of dissolved gas (1)

Accordingly, the amount of gas bubbles can be decreased either by decreasing the amount of generated gas or by increasing the amount of dissolved gas.

The dissolution speed of gas and the dissolution capacity of gas in a liquid is proportional to the product of the gas dissolution amount (C) per unit volume of the liquid (constant temperature, 1 kg cm²), the liquid volume (V), and the difference (P-P₀) between the liquid pressure (=gas partial pressure) (P) and the gas partial pressure (P₀) corresponding to the initial amount of dissolved gas:
Gas dissolution speed & gas dissolution capacity in liquid ∝C×V×(P−P₀) (2)

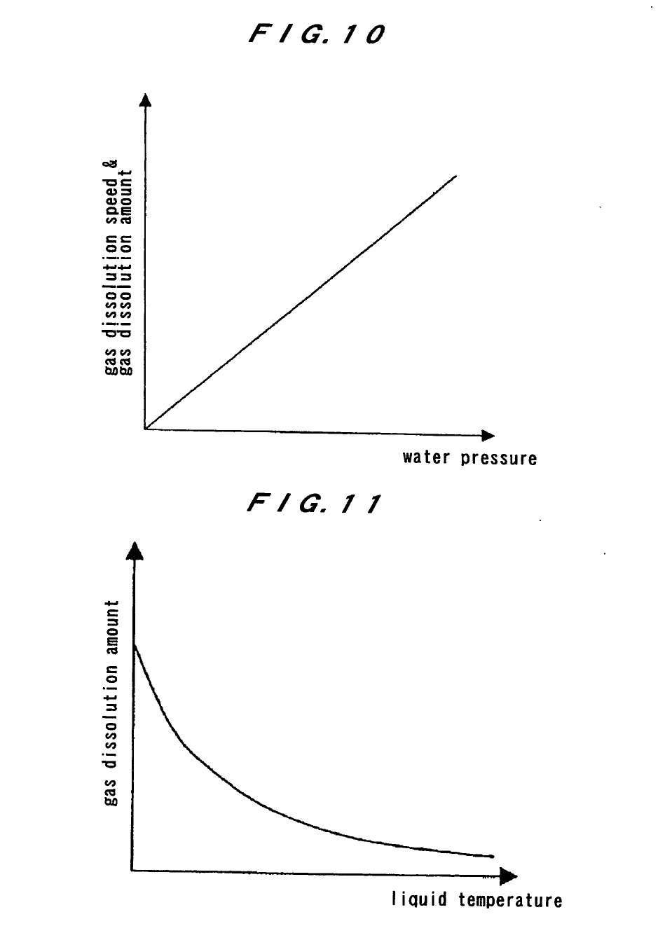

Accordingly, the relationship between the gas dissolution speed & gas dissolution capacity in liquid and the liquid pressure (water pressure) is as shown in FIG. 10. Thus, the gas dissolution speed and the gas dissolution capacity in a liquid increase in proportion to the liquid pressure, while from the equation (1), the amount of gas bubbles generated is determined as the difference between the amount of gas generated and the amount of gas dissolved in the liquid. Accordingly, by carrying out electrolytic processing in the presence of a high-pressure liquid, the dissolution speed and the dissolution amount of a gas generated at the surfaces of an electrode and a workpiece can be increased and, therefore, the amount of gas bubbles generated at the gas generation sites can be decreased, whereby the formation of pits can be decreased.

The gas dissolution amount (C) per unit volume of liquid in the formula (2) decreases with an increase in the liquid temperature. Thus, the relationship between the gas dissolution amount and the liquid temperature is as shown in FIG. 11. Accordingly, by lowering the temperature of the high-pressure liquid to be supplied into the pressure tight container 200, the gas dissolution speed and the gas dissolution capacity in the liquid can be increased, whereby the amount of gas bubbles generated at the gas generation sites can be decreased and, at the same time, expansion of the gas due to the liquid temperature can be suppressed.

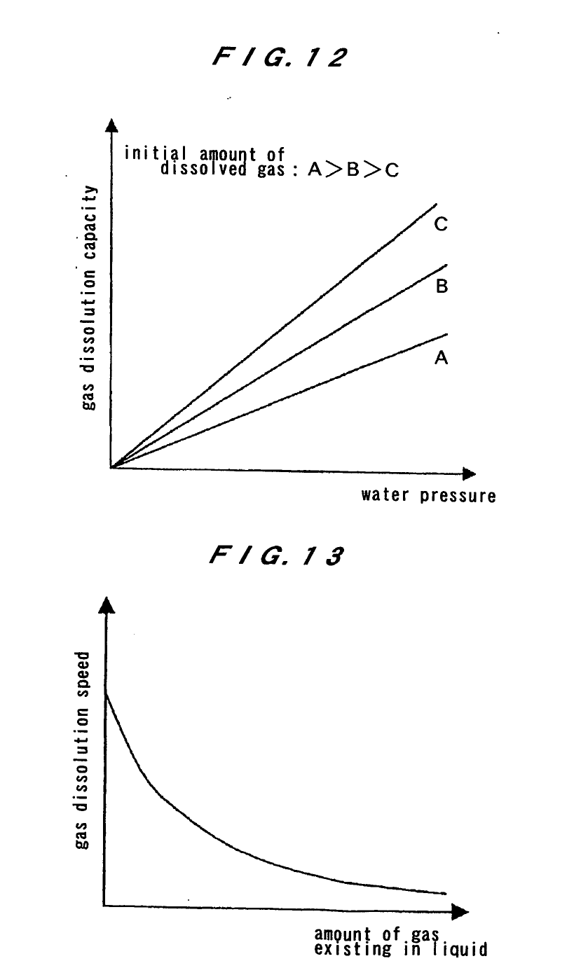

Further, as shown in the formula (2), when an initial dissolved gas is present in a liquid, the gas dissolution capacity decreases by the gas partial pressure (P₀) corresponding to the initial amount of dissolved gas. Accordingly, with respect to liquids A, B and C with the initial amount of dissolved gas higher in this order (A>B>C), the relationship between the liquid pressure (water pressure) and the gas dissolution capacity is as shown in FIG. 12. Further, the gas dissolution speed decreases with an increase of the amount of gas existing in liquid, because the dissolution capacity of the remaining gas decreases. Thus, the relationship between the amount of gas existing in liquid and the gas dissolution speed is as shown in FIG. 13. Accordingly, by previously releasing dissolved gas from the high-pressure liquid in advance of its supply into the pressure tight container, the gas dissolution capacity and the gas dissolution speed in the liquid can be increased, whereby the amount of gas bubbles generated at the gas generation sites can be decreased.

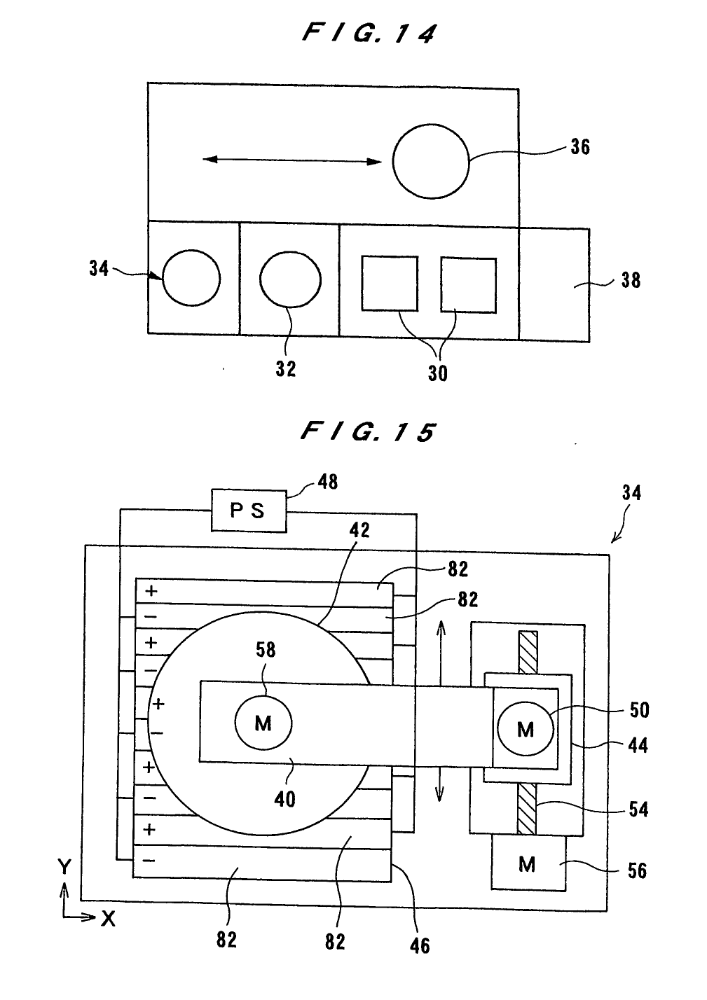

FIG. 14 is a plan view illustrating a construction of a substrate processing apparatus provided with an electrolytic processing apparatus according to a second embodiment of the present invention. As shown in FIG. 14, the substrate processing apparatus comprises a pair of the loading/unloading units 30 as a carry-in and carry-out section for carrying in and carrying out a substrate W, e.g. a substrate W as shown in FIG. 1B, the reversing machine 32 for reversing the substrate W, and an electrolytic processing device 34. These devices are disposed in series. A transport robot 36 as a transport device, which can move parallel to these devices for transporting and transferring the substrate W therebetween, is provided. The substrate processing apparatus is also provided with a monitor section 38, adjacent to the loading/unloading units 30, for monitoring a voltage applied between the bellow-described processing electrodes and the feeding electrodes upon electrolytic processing in the electrolytic processing device 34, or an electric current flowing therebetween.

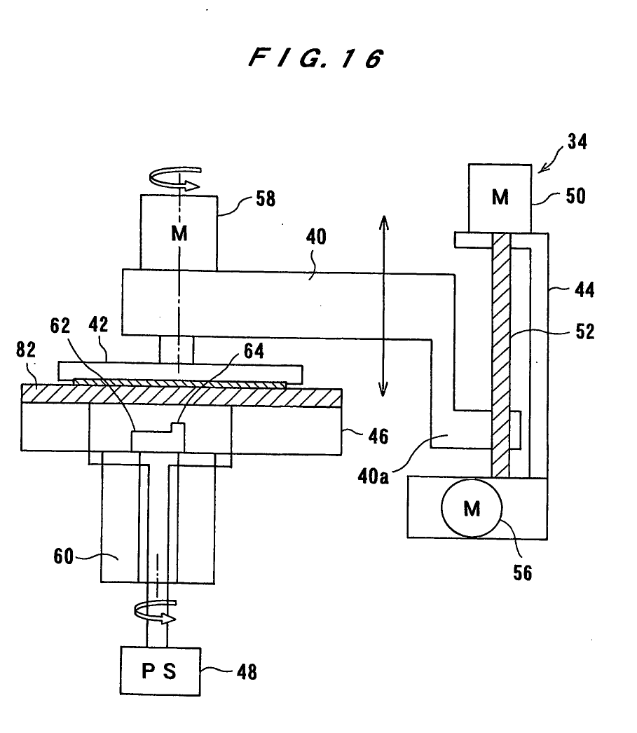

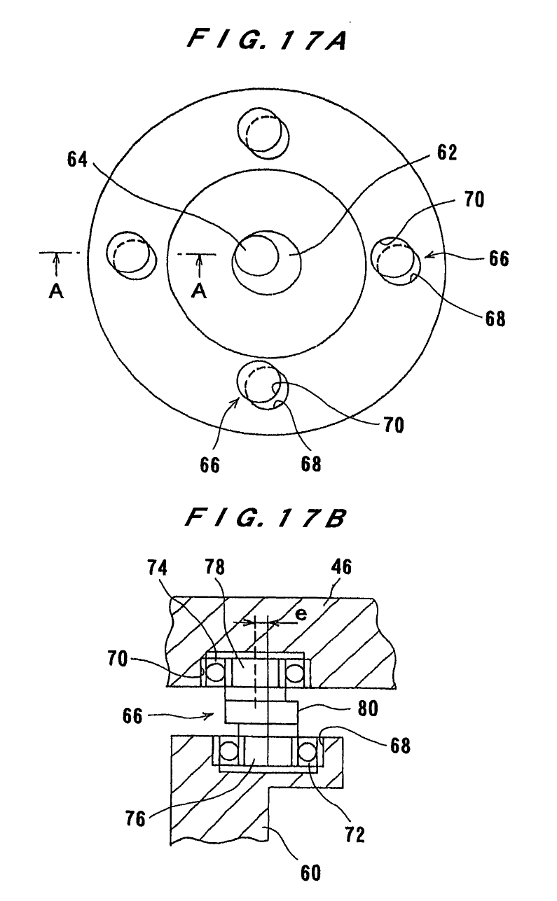

FIG. 15 is a plan view of the electrolytic processing apparatus 34 provided in the substrate processing apparatus, and FIG. 16 is a vertical sectional view of FIG. 15. As shown in FIGS. 15 and 16, the electrolytic processing apparatus 34 includes an arm 40 that can move vertically and make a reciprocation movement in a horizontal plane, a substrate holder 42, supported vertically at the free end of the arm 40, for attracting and holding the substrate W with its front surface facing downwardly (face-down), moveable flame 44 to which the arm 40 is attached, a rectangular electrode section 46, and a power source 48 connected to the electrode section 46. In this embodiment, the size of the electrode section 46 is designed to have a slightly larger diameter than the diameter of the substrate W to be held by the substrate holder 42.

As shown in FIGS. 15 and 16, a vertical-movement motor 50 is mounted on the upper end of the moveable flame 44. A ball screw 52, which extends vertically, is connected to the vertical-movement motor 50. Abase 40a of the arm 40 is connected to a ball screw 52 so that the arm 40 moves vertically via the ball screw 52 by the actuation of the vertical-movement motor 50. The moveable flame 44 per se is connected to a ball screw 54 that extends horizontally, so that the moveable flame 44 and the arm 40 make a reciprocation movement in a horizontal plane by the actuation of a reciprocating motor 56.

The substrate holder 42 is connected to a substrate-rotating motor 58 supported at the free end of the arm 40. The substrate holder 42 is rotated (about its axis) by the actuation of the substrate-rotating motor 58. The arm 40 can move vertically and make a reciprocation movement in the horizontal direction, as described above, the substrate holder 42 can move vertically and make a reciprocation movement in the horizontal direction together with the arm 40.

The hollow motor 60 is disposed below the electrode section 46. A drive end 64 is formed at the upper end portion of the main shaft 62 of the hollow motor 60 and arranged eccentrically position to the center of the main shaft 62. The electrode section 46 is rotatably coupled to the drive end 64 via a bearing (not shown) at the center portion thereof. Three or more of rotation-prevention mechanisms are provided in the circumferential direction between the electrode section 46 and the hollow motor 60.

FIG. 17A is a plan view showing the rotation-prevention mechanisms of this embodiment, and FIG. 17B is a cross-sectional view taken along the line A-A of FIG. 17A. As shown in FIGS. 17A and 17B, three or more (four in FIG. 17A) of rotation-prevention mechanisms 66 are provided in the circumferential direction between the electrode section 46 and the hollow motor 60. As shown in FIG. 17B, a plurality of depressions 68, 70 are formed at equal intervals in the circumferential direction at the corresponding positions in the upper surface of the hollow motor 60 and in the lower surface of the electrode section 46. Bearings 72, 74 are fixed in each depression 68, 70, respectively. A connecting member 80, which has two shafts 76, 78 that are eccentric to each other by eccentricity “e”, is coupled to each pair of the bearings 72, 74 by inserting the respective ends of the shafts 76, 78 into the bearings 72, 74. The eccentricity of the drive end 64 against to the center of the main shaft 62 of the hollow motor 60 is also “e”. Accordingly, the electrode section 46 is allowed to make a revolutionary movement with the distance between the center of the main shaft 62 and the drive end 64 as radius “e”, without rotation about its own axis, i.e. the so-called scroll movement (translational rotation movement) by the actuation of the hollow motor 60.

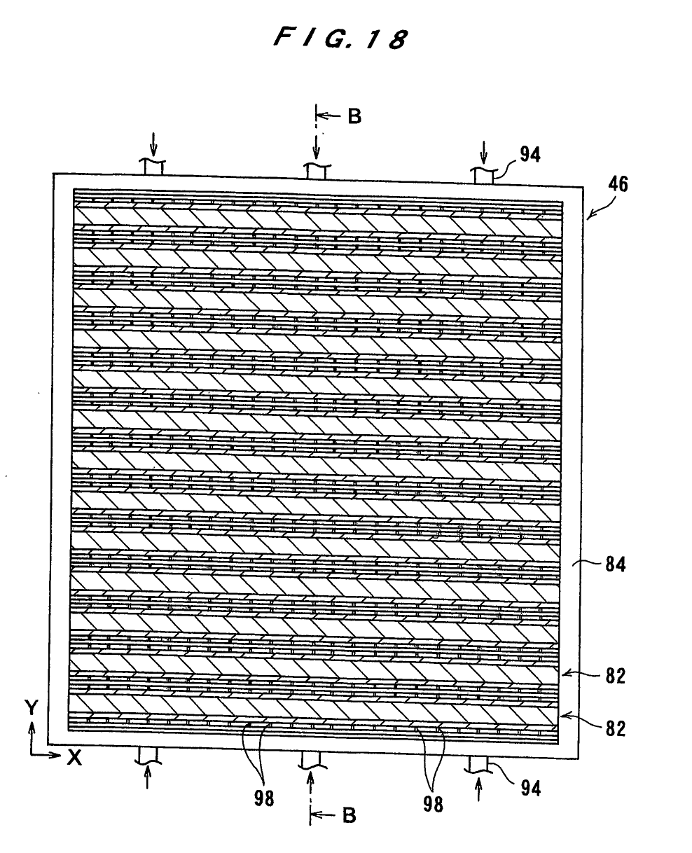

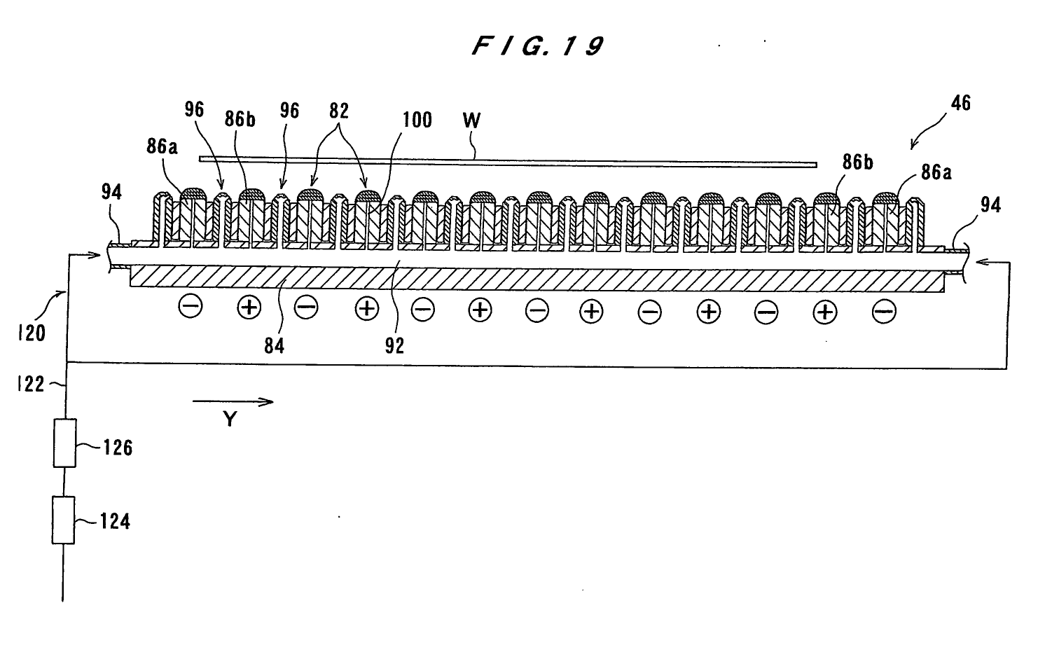

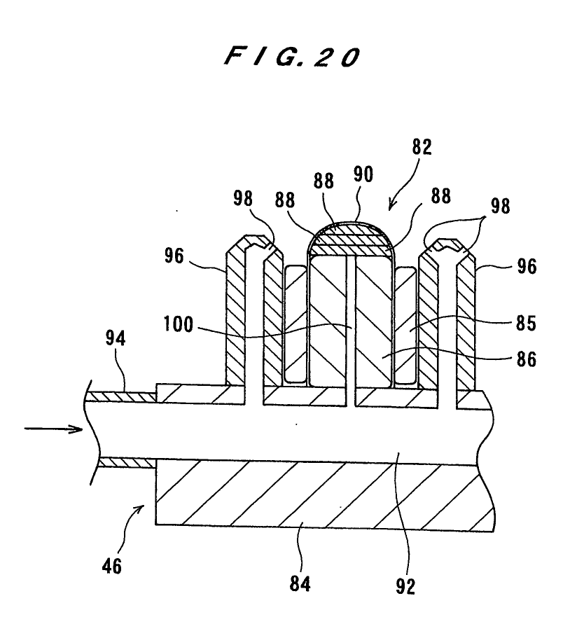

Next, the electrode section 46 according to this embodiment will now be described. The electrode section 46 of this embodiment includes a plurality of electrode members 82. FIG. 18 is a plan view of the electrode section 46 of this embodiment, FIG. 19 is a sectional view taken along the line B-B of FIG. 18, and FIG. 20 is an enlarged view of a portion of FIG. 19. As shown FIGS. 19 and 20, the electrode section 46 includes a plurality of electrode members 82 which extend in the X direction (see FIGS. 15 and 18), and are disposed in parallel at an even pitch on a tabular base 84.

As shown in FIG. 20, each electrode member 82 comprises an electrode 86 to be connected to a power source 48 (see FIGS. 1 and 16), an ion exchanger 88 laminated on the top of the electrode 86, and an ion exchanger (ion exchange membrane) 90 covering the surfaces of the electrode 86 and the ion exchanger 88 integrally. The ion exchanger 90 is mounted to the electrode 86 via holding plates 85 disposed on both sides of the electrode 86.

The ion exchangers 88, 90 should meet the following four requisites:

(1) Removal of Processing Products (Including a Gas)

This is closely related to stability of the processing rate and evenness in the distribution of processing rate. To meet this demand, it is preferable to use an ion exchanger having “water permeability” and “water-absorbing properties”. By the term “water permeability” is herein meant a permeability in a broad sense. Thus, the member, which itself has no water permeability but can permit permeation therethrough of water by the provision of holes or grooves, is herein included as a “water-permeable” member. The term “water-absorbing properties” means properties of absorbing water and allowing water to penetrate into the material.

(2) Stability of Processing Rate

To meet this demand, it is desirable to use a multi-layer laminated ion exchanger, thereby securing an adequate ion-exchange capacity.

(3) Flatness of Processed Surface (Ability of Eliminating Level Differences)

To meet this demand, the processing surface of the ion exchanger desirably has a good surface smoothness. Further, in general, the harder the member is, the flatter is the processed surface (ability of eliminating level differences).

(4) Long Life

In the light of long mechanical life of the member, it is desirable to use an ion-exchange material having a high wear resistance.

It is preferred to use as the ion exchanger 88 an ion exchanger having a large ion exchange capacity. According to this embodiment, the ion exchanger 88 has a multi-layer structure of a laminate of three 1 mm-thick (non-woven fabric ion exchangers), and thus has an increased total ion exchange capacity. The use of such an ion exchanger having a large ion exchange capacity can prevent the processing products (oxides and ions) produced by the electrolytic reaction from accumulating in the ion exchanger 88 in an amount exceeding the accumulation capacity of the ion exchanger 88. This can prevent the processing products accumulated in the ion exchanger 88 from changing their forms and adversely affecting the processing rate and its distribution. Further, an ion exchange capacity enough for treating a desired processing amount of workpiece can be secured. The ion exchanger 88 may be of a single membrane, when its ion exchange capacity is sufficiently high.

It is preferred that at least the ion exchanger 90 to be opposed to a workpiece has a high hardness and a good surface smoothness. The term “high hardness” herein means high rigidity and low compression elastic modulus. The ion exchanger having a high hardness, when used in processing of the workpiece having fine irregularities in the surface, hardly follows the irregularities and is therefore likely to selectively remove only the raised portions in the surface of the workpiece. The expression “has a surface smooth” herein means that the surface has small irregularities. The ion exchanger having a surface smoothness is less likely to contact the depressed portions in the surface of the workpiece, and is more likely to selectively (preferentially) remove only the raised portions. According to this embodiment, by thus combining the ion exchanger 90 having a surface smoothness with the ion exchanger 88 having a large ion exchange capacity, the defect of small ion exchange capacity of the ion exchanger 90 is compensated for by the ion exchanger 88.

Further, it is preferred to use an ion exchanger having an excellent water permeability as the ion exchanger 90. By permitting pure water or ultrapure water to flow through the ion exchanger 90, a sufficient amount of water can be supplied to a functional group (sulfonic acid group in the case of a strongly acidic cation-exchange material) to thereby increase the amount of dissociated water molecules, and the processing products (including gasses) formed by the reaction between the to-be-processed material and hydroxide ions (or OH radicals) can be removed by the flow of water, whereby the processing efficiency can be enhanced. The flow of pure water or ultrapure water is thus necessary, and the flow of pure water or ultrapure water should desirably be constant and uniform. The constancy and uniformity of the flow of pure water or ultrapure water lead to constancy and uniformity in the supply of ions and the removal of the process product, which in turn lead to constancy and uniformity in the processing.

This invention is not limited to electrolytic processing using an ion exchanger. When using, for example, an electrolytic solution as a processing liquid, a processing member (contact member) to be mounted on the surfaces of the electrodes is not limited to ion exchangers 88, 90 which are the most suitable for pure water or ultrapure water, but a soft polishing pad or non-woven fabric, or the like may also be used. Politex (trademark of Rodel Products Corporation), a polyurethane sponge, a non-woven fabric, a foamed polyurethane or a PVD sponge may be used as a contact member.

According to this embodiment, the electrodes 86 of adjacent electrode members 82 are connected alternately to the cathode and to the anode of the power source 48. For example, an electrode 86a (see FIG. 19) is connected to the cathode of the power source 48 and an electrode 86b (see FIG. 19) is connected to the anode. When processing copper, for example, the electrolytic processing action occurs on the cathode side, and therefore the electrode 86a connected to the cathode of the power source 48 becomes a processing electrode, and the electrode 86b connected to the anode of the power source 48 becomes a feeding electrode. Thus, according to this embodiment, the processing electrodes 86a and the feeding electrodes 86b are disposed in parallel and alternately.

As previously stated, depending upon the material to be processed, the electrode connected to the cathode of the power source may serve as a feeding electrode, and the electrode connected to the anode may serve as a processing electrode.

Further, in the case where the to-be-processed material is a conductive oxide such as tin oxide or indium tin oxide (ITO), electrolytic processing is carried out after reducing the to-be-processed material. More specifically, with reference to FIG. 16, the electrodes connected to the anode of the power source 48 serve as reduction electrodes, and the electrodes connected to the cathode serve as feeding electrodes to effect reduction of the conductive oxide. Subsequently, processing of the reduced conductive material is carried out by making the previous feeding electrodes serve as the processing electrodes. Alternatively, the polarity of the reduction electrodes at the time of reduction of the conductive oxide may be reversed so that the reduction electrodes can serve as the processing electrodes. Removal processing of the conductive oxide may also be effected by making the to-be-processed material serve as a cathode and allowing it to face an anode electrode.

According to the above-described embodiment, though a copper film 6 as a conductor film formed in the surface of the substrate is processed by electrolytic processing, an unnecessary ruthenium (Ru) film formed on or adhering to the surface of a substrate may be processed (etched and removed) by electrolytic processing in the same manner by making the ruthenium film serve as a anode and the electrodes connected to the cathode serve as processing electrodes.

By thus disposing the processing electrodes and the feeding electrodes alternately in the Y direction (perpendicular direction to the longitudinal direction of the electrode members 82) of the electrode section 46, fixed feeding portions to supply electricity to a conductive film (portion to be processed) of the substrate is not needed, and processing can be effected to the entire surface of the substrate.

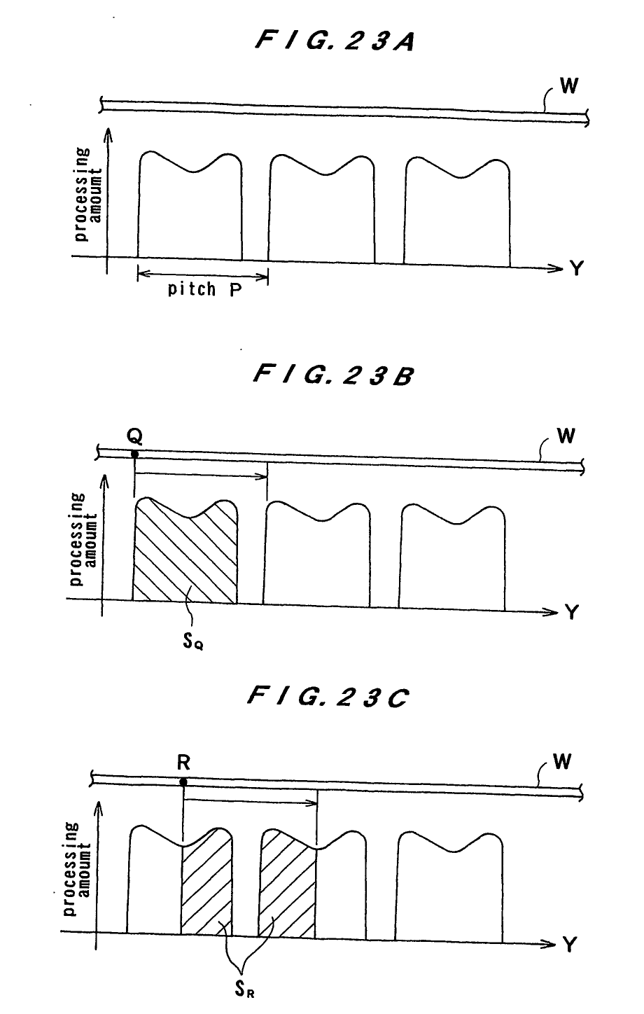

According to this embodiment, in addition to the scroll movement (first relative movement), the substrate W held by the substrate holder 42 is moved in the Y direction for a predetermined distance during electrolytic processing to thereby allow the substrate Wand the electrode members 82 to make a second relative movement, thereby eliminating the variation in the processing amount. Thus, as shown in FIG. 23A, when only the scroll movement (first relative movement) is carried out in electrolytic processing, a difference in the processing amount of the substrate W is produced in the Y direction, and the processing amount distribution in the Y direction, comprising processing amount distribution units of the same figure appearing every pitch P, is obtained. During the electrolytic processing, the reciprocating motor 56 is driven to move the arm 40 and the substrate holder 42 in the Y direction for a distance corresponding to an integral multiple of the pitch P shown in FIG. 23A, thereby carrying out the second relative movement between the substrate W and the electrode members 82. When carrying out such a second relative movement together with the first relative movement, for example, for a distance corresponding to the pitch P, a point Q in the substrate W, shown in FIG. 23B, is processed in an amount corresponding to the area S_{Q}, while a point R in the substrate W, shown in FIG. 23C, is processed in an amount corresponding to the area S_{R}. Since the respective processing amount distribution units are of the same figure, the area S_{Q} is equal to the area S_{R}, that is, the processing amount at the point Q of the substrate W is equal to that at the point R. Thus, carrying out the second relative movement together with the first relative movement makes it possible to process the entire surface of the substrate W uniformly. In this case, it is preferred that the speed of the second relative movement be constant.

As shown in FIG. 19, a flow passage 92 for supplying pure water, more preferably ultrapure water, to the processing surface is formed in the interior of the base 84 of the electrode section 46, and the flow passage 92 is connected to a pure water supply system 120 via a pure water supply pipe 94. The pure water supply system 120 includes a pure water line 122. In the pure water line 122 are provided a heat exchanger 124 for adjusting the temperature of pure water flowing along the pure water line 122, and a degassing device 126 for releasing dissolved gas from pure water flowing along the pure water line 122. As with the preceding embodiment, pure water flowing along the pure water line 122 is first passed through the heat exchanger 124, where pure water is cooled so that its temperature becomes not higher than 25° C., and pure water is then passed through the degassing device 126 to remove (release) an initial dissolved gas.

On either side of each electrode member 82, there are provided pure water jet nozzles 96 for jetting above-described pure water or ultrapure water, which has been cooled (temperature-adjusted) during its passage through the heat-exchanger 124 and degassed during its passage through the degassing device 126, and supplied from the flow passage 92, to between the substrate W and the ion exchanger 90 of the electrode member 82. In each pure water jet nozzle 96, a plurality of jet ports 98 are provided along the X direction (see FIG. 18) for jetting pure water or ultrapure water toward the processing surface of the substrate W facing the electrode member 82, i.e., the portion of the substrate W in contact with the ion exchanger 90. Pure water or ultrapure water in the flow passage 92 is supplied from the jet ports 98 of the pure water jet nozzles 96 to the entire processing surface of the substrate W. As shown in FIG. 20, the height of each pure water jet nozzle 96 is lower than the height of the ion exchanger 90 of each electrode member 82, so that the top of the pure water jet nozzle 96 does not contact the substrate W upon contact of the substrate W with the ion exchanger 90 of the electrode member 82.

Through-holes 100, communicating with the flow passage 92 and the ion exchanger 88, are formed inside the electrode 86 of each electrode member 82. Pure water or ultrapure water in the flow passage 92 is thus supplied through the through-holes 100 to the ion exchanger 88. As with the preceding embodiment, instead of pure water, or more preferably ultrapure water, a liquid having an electric conductivity of not more than 500 μS/cm or an electrolytic solution may also be used.

Next, substrate processing (electrolytic processing) by using this electrolytic processing apparatus will be described. First, a substrate W, e.g. a substrate W, as shown in FIG. 1B, which has in its surface a copper film 6 as a conductive film (to-be-processed portion), is taken by the transport robot 36 out of the cassette housing substrates and set in the loading/unloading section 30. If necessary, the substrate W is transferred to the reversing machine 32 by the transport robot 36 to reverse the substrate W so that the front surface of the substrate W having the conductor film (copper film 6) faces downwardly.

Then, the transport robot 36 receives the reversed substrate W and transfers it to the electrolytic processing apparatus 34. The substrate W is attracted and held by the substrate holder 42. The arm 40 is moved to move the substrate holder 42 holding the substrate W to a processing position right above the electrode section 46. Next, the vertical-movement motor 50 is driven to lower the substrate holder 42 so as to bring the substrate W held by the substrate holder 42 close to or into contact with the surface of the ion exchangers 90 of the electrode section 46. Thereafter, the substrate-rotating motor 58 is driven to rotate the substrate W and, at the same time, the hollow motor 60 is driven to make the electrode section 46 a scroll movement. At this time, pure water or ultrapure water is jetted from the jet ports 98 of the pure water jet nozzles 96 to between the substrate W and the electrode members 82, and pure water or ultrapure water is supplied to the ion exchangers 88 through the through-holes 100 of the electrode section 46. In this embodiment, pure water or ultrapure water supplied to the ion exchangers 88 is discharged from the end portion in the longitudinal direction of each electrode member 82.

Then, a given voltage is applied from the power source 48 to between the processing electrodes and the feeding electrodes, and electrolytic processing of the conductive film (copper film 6) in the surface of the substrate W is carried out at the processing electrodes (cathodes) through the action of hydrogen ions or hydroxide ions produced by the ion exchangers 88, 90. According to this embodiment, processing is carried out by rotating the substrate holder 42 and, at the same time, allowing the electrode section to make scroll movement. The arm 40 and the substrate holder 42 may be moved in Y direction by the actuation of the reciprocating motor 56 during electrolytic processing.

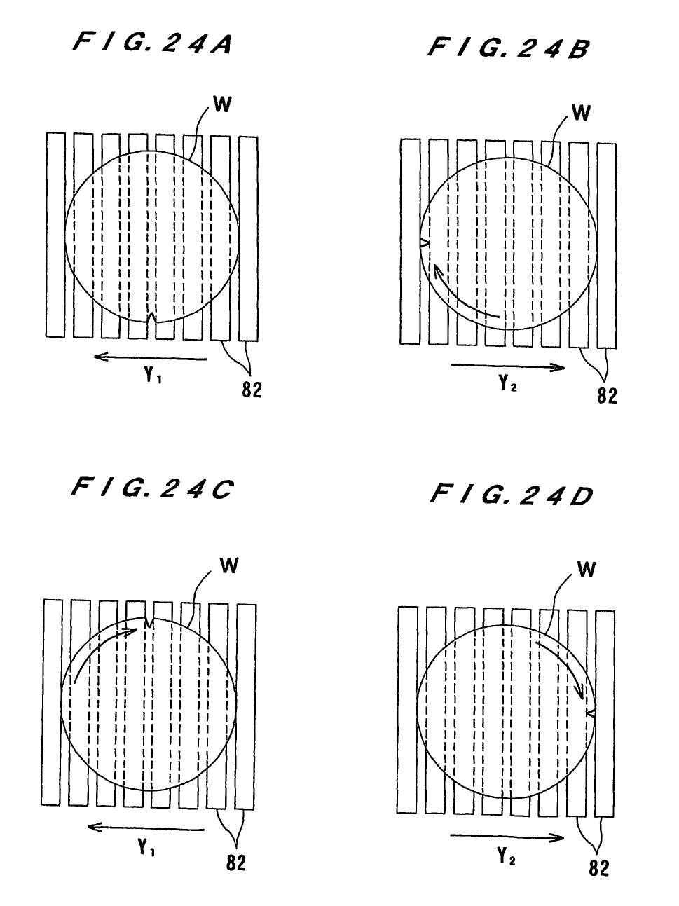

Thus, from the position shown in FIG. 24A, the substrate W is moved relative to the electrode members 82 in the Y₁ direction for a distance corresponding to an integral multiple of the pitch P, described above. Next, the substrate-rotating motor 58 is driven to counterclockwise rotate the substrate W 90 degrees, and then the substrate W is moved in the Y₂ direction for a distance corresponding to an integral multiple of the pitch P (see FIG. 24B). Similarly, after counterclockwise rotating the substrate W 90 degrees, the substrate W is moved in the Y₁ direction for an integral multiple of the pitch P (see FIG. 24C). Further, after counterclockwise rotating the substrate W 90 degrees, the substrate W is moved in the Y₂ direction for an integral multiple of the pitch P (see FIG. 24D). By thus changing the moving direction of the substrate W every forward movement (movement in the Y₁ direction) and the every backward movement (movement in the Y₂ direction) in the second relative movement, even when there is some variation in the processing rate among the processing electrodes, the variation can be evened out on the substrate W and the unevenness of processing can be eliminated as a whole.

It is possible to allow the substrate W to make a scroll movement. Further, instead of the scroll movement, it is possible to employ a translatory reciprocating movement in the Y direction.

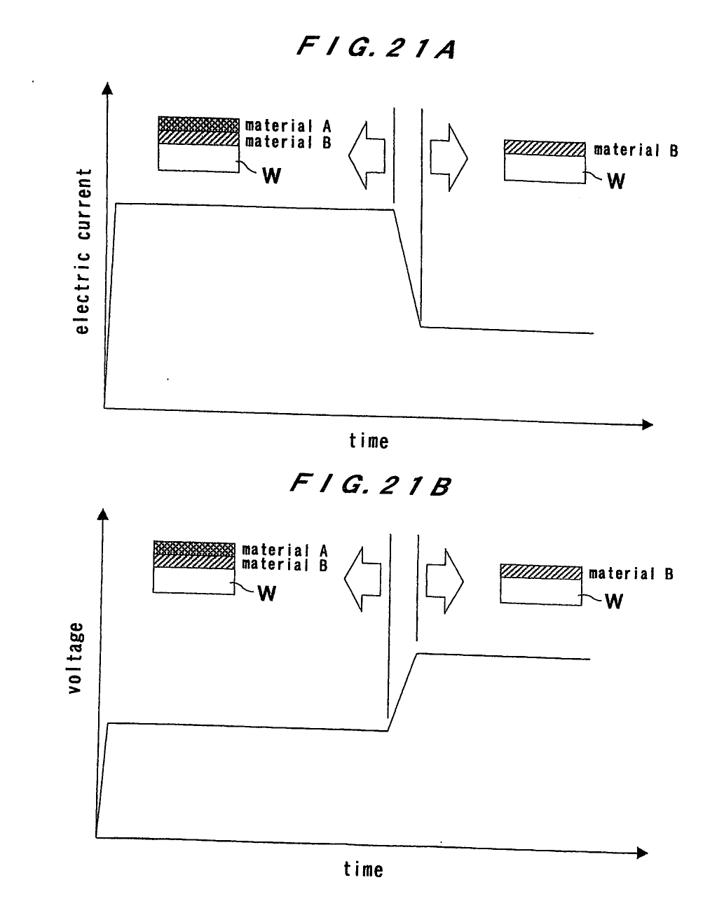

The monitor section 38 monitors the voltage applied between the processing electrodes and the feeding electrodes or the electric current flowing therebetween to detect the end point (terminal of processing). It is noted in this connection that in electrolytic processing an electric current (applied voltage) varies, depending upon the material to be processed, even with the same voltage (electric current). For example, as shown in FIG. 21A, when an electric current is monitored in electrolytic processing of the surface of a substrate W to which a film of material B and a film of material A are laminated in this order, a constant electric current is observed during the processing of material A, but it changes upon the shift to the processing of the different material B. Likewise, when a voltage applied between the processing electrodes and the feeding electrodes is monitored, as shown in FIG. 21B, though a constant voltage is applied between the processing electrodes and the feeding electrodes during the processing of material A, the voltage applied changes upon the shift to the processing of the different material B. FIG. 21A illustrates, by way of example, a case in which an electric current is harder to flow in electrolytic processing of material B compared to electrolytic processing of material A, and FIG. 21B illustrates a case in which the applied voltage becomes higher in electrolytic processing of material B compared to electrolytic processing of material A. As will be appreciated from the above-described example, the monitoring of changes in electric current or in voltage can surely detect the end point.

Though this embodiment shows the case where the monitor section 38 monitors the voltage applied between the processing electrodes and the feeding electrodes, or the electric current flowing therebetween to detect the end point of processing, it is also possible to allow the monitor section 38 to monitor a change in the state of the substrate being processed to detect an arbitrarily set end point of processing. In this case, “the end point of processing” refers to a point at which a desired processing amount is attained for a specified region in a surface to be processed, or a point at which an amount corresponding to a desired processing amount is attained in terms of a parameter correlated with a processing amount for a specified region in a surface to be processed. By thus arbitrarily setting and detecting the end point of processing even in the middle of processing, it becomes possible to conduct a multi-step electrolytic processing.

After completion of the electrolytic processing, the power source 48 is disconnected, and the rotation of the substrate holder 42 and the electrode section 46 are stopped. Thereafter, the substrate holder 42 is raised, and substrate W is transferred to the transport robot 36 after moving the arm 40. The transport robot 36 takes the substrate W from the substrate holder 42 and, if necessary, transfers the substrate W to the reversing machine 32 for reversing it, and then returns the substrate W to the cassette in the loading/unloading unit 30.

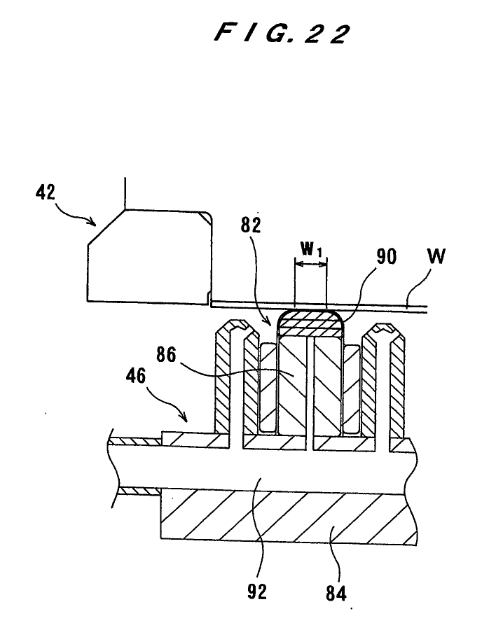

In electrolytic processing carried out by contacting the substrate W and the ion exchanger 90 of each electrode member 82, processing proceeds within the contact area between the ion exchanger 90 of the electrode section 46 and the processing surface of the substrate W. According to this embodiment, as shown in FIG. 22, the ion exchanger 90 and the processing surface of the substrate W contact each other linearly with the contact width W₁ of 0.1 to 1.5 mm, preferably 0.2 to 1.2 mm, more preferably 0.2 to 1.0 mm during electrolytic processing. Further, during electrolytic processing, the electrode section 46 makes a scroll movement while the substrate W held by the substrate holder 42 is rotating. The relative speed of the relative movement between the electrode section 46 and the substrate W is made not lower than 0.2 m/sec, preferably not lower than 0.5 m/sec, more preferably not lower than 0.7 m/sec. This can prevent the formation of pits in the processing surface of a conductive film, for example the copper film 6 shown in FIG. 1B, on the substrate W. The mechanism of the prevention of pit formation will be described below.

Further, because of the above-described mechanism, the formation of pits in the processing surface of the substrate W can also be prevented by the jetting (supply) of pure water or ultrapure water, which has been cooled (temperature-adjusted) during its passage through the heat exchanger 124 and degassed during its passage through the degassing device 126, and supplied from the flow passage 92, to between the substrate W and the ion exchanger 90 of each electrode member 82.

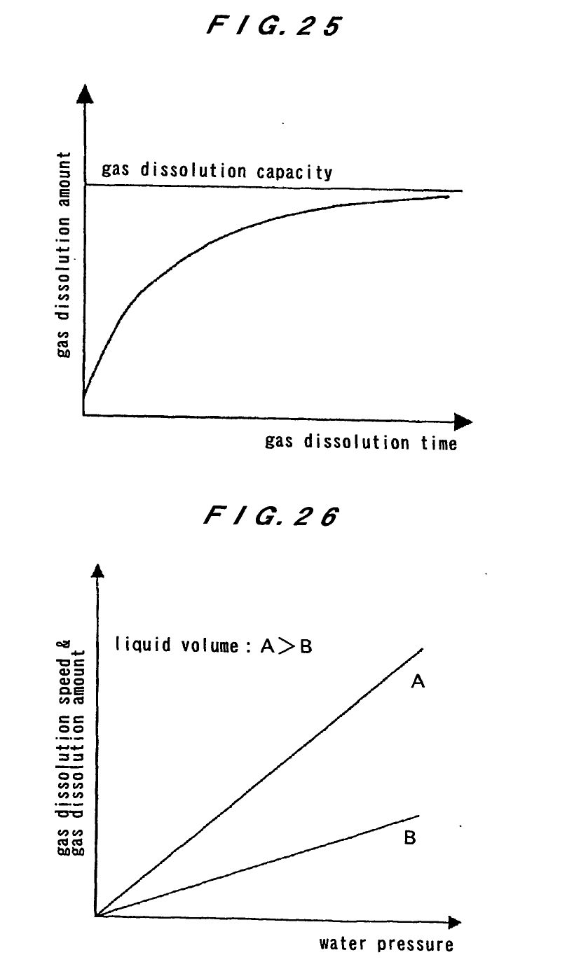

As shown in FIG. 25, the dissolution amount of a gas in a liquid increases with the gas dissolution time and finally approximates the gas dissolution capacity. Thus, the longer the gas dissolution time, the larger is the gas dissolution amount in the liquid. By narrowing the contact width W₁ of the linear contact area between the ion exchanger 90, covering each electrode 86, and the substrate W held by the substrate holder 42, the passing time (processing time) of the electrode 86 for a processing point on the substrate W can be shortened. This shortens the gas generation time and lengthens the gas dissolution time, thereby increasing the gas dissolution amount and decreasing the amount of gas bubbles generated at the gas generation sites.

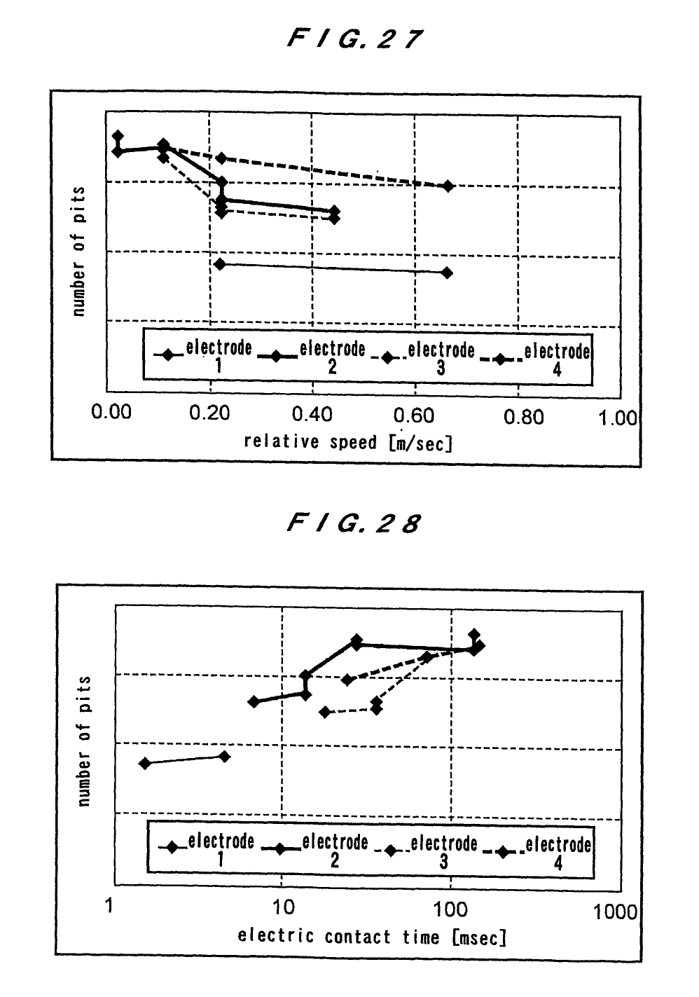

FIG. 27 shows the relationship between the relative speed (between a substrate W and an electrode) and the number of pits formed in the electrode in electrolytic processing carried out by using electrodes 1 through 4 respectively having the electrode width shown in Table 1 below and setting the contact widths between the respective ion exchangers and the processing surface of the substrate W as shown in Table 1. In this experiment, the contact width between the ion exchanger and the processing surface of the substrate is determined by the tension and the curvature of the ion exchanger mounted on the electrode, and measures for restriction of the contact area, such as attachment of an insulating film to the ion exchanger, are not taken.

TABLE 1

| | Electrode 1 | Electrode 2 | Electrode 3 | Electrode 4 |
|---|---|---|---|---|
| Electrode width | 1.5 mm | 8 mm | 16 mm | 24 mm |
| Ion exchanger | 1 mm | 3 mm | 8 mm | 16 mm |
| contact width | | | | |

As apparent from comparison in FIG. 27 of the number of pits between the electrodes 1 through 4 with the same relative speed of 0.22 m/sec, especially good results are obtained with the electrode 1 of which the contact width between the ion exchanger and the processing surface of the substrate is as narrow as 1 mm.

Further, in electrolytic processing, a gas generated dissolves in the liquid present between the electrodes 86 and the substrate W. FIG. 26 shows the relationship between the liquid pressure (water pressure) and the gas dissolution speed and the gas dissolution amount of a gas which dissolves in liquid volumes A and B (A>B). Accordingly, by making the relative speed between the electrodes 86 and the substrate W larger to thereby make larger the volume or flow rate of the liquid between the electrodes 86 and the substrate W to be replaced with the relative movement between the electrodes 86 and the substrate W, the amount of gas bubbles generated at the gas generation sites can be decreased.

This is apparent also from the above-described FIG. 27. FIG. 27 shows a decrease in the number of pits with an increase in the relative speed between the electrodes 86 and the substrate W.

FIG. 28 shows the relationship between the number of pits and the contact time of each of the electrodes (ion exchangers) 1 through 4 with a point in the processing surface of the substrate. As can be seen from FIG. 28, the number of pits decreases with a decrease in the contact time of the electrode (ion exchanger) with a point in the processing surface of the substrate.

The contact time of the electrode 86 (ion exchanger 96) with a point in the processing surface of the substrate W, which can be determined by the preferred values for the contact width W₁ between the ion exchanger 90 and the processing surface of the substrate W and by the preferred values for the relative movement speed between the electrode section 46 and the substrate W, is generally not more than 10 msec, preferably not more than 5 msec, more preferably not more than 1.5 msec.

Though in this embodiment electrolytic processing is carried out by always applying a voltage from the power source 48 to the electrodes 86, it is also possible to perform an on/off control of the power source 48 in synchronization with the relative scroll movement between the electrode section 46 and the substrate W.

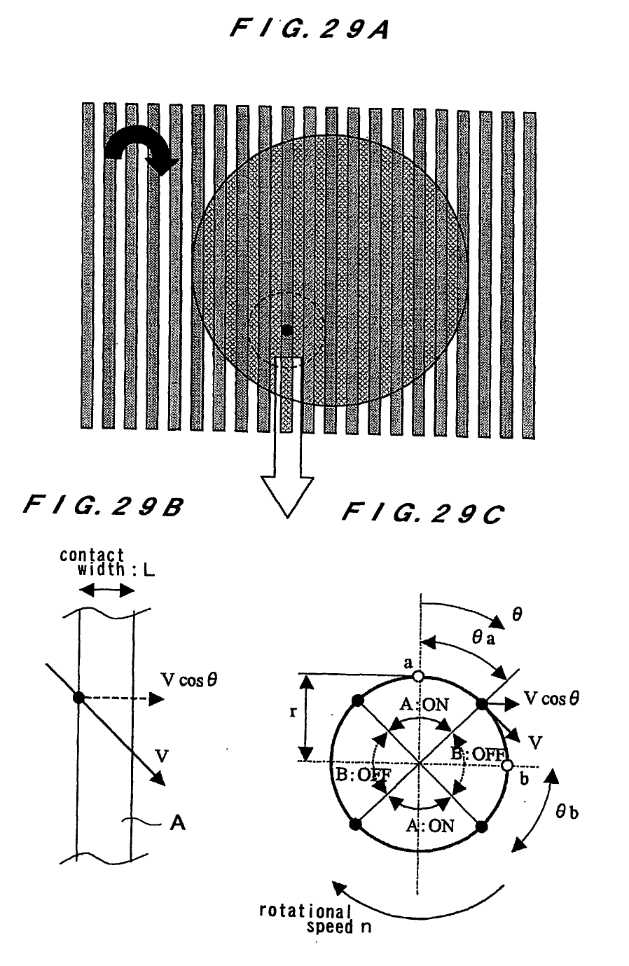

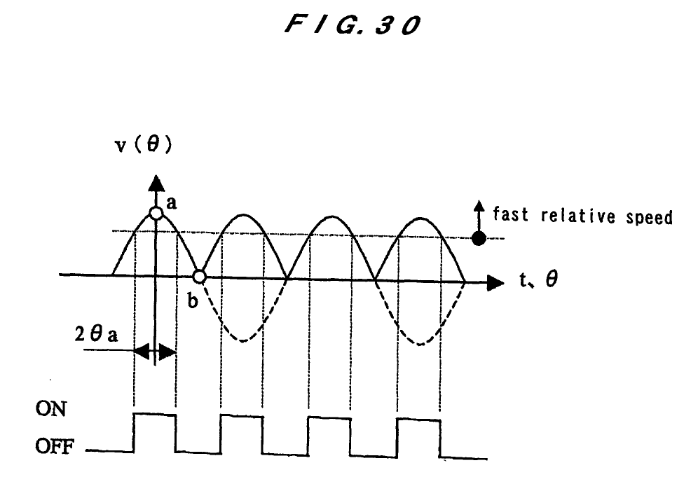

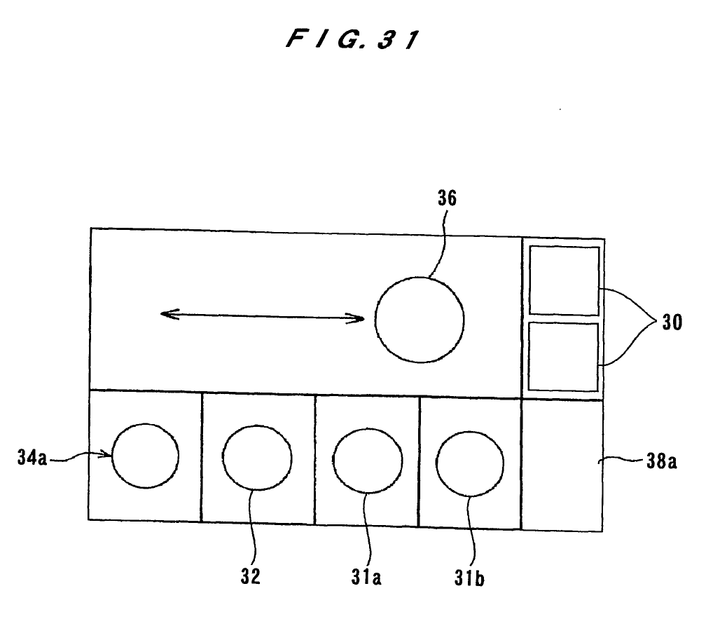

In the scroll movement, for example, a relative speed V cos θ in a direction perpendicular to an electrode (ion exchanger) A, as shown in FIG. 29B, is always changing, and there are a point at which the relative speed becomes the maximum (point “a” in FIG. 29C) and a point at which the relative speed becomes zero (point “b” in FIG. 29C). Accordingly, by synchronizing the scroll movement with the on/off control of the power source 48 such that the power source 48 is on to carry out processing only within intervals during which the relative speed of the scroll movement is fast, as shown in FIG. 30, the same pit decreasing effect as by the above-described high relative speed can be produced. The on/off control of the power source 48 in synchronization with the scroll movement can be performed, for example, by detecting the angle of rotation of a table, which is making the scroll movement, based on a pulse signal coming from a rotating motor for scroll movement or a signal from a position sensor provided in the table, and performing the on/off operation of the power source in conjunction with the detection.

By thus synchronizing the scroll movement with the on/off control of the power source so that processing is carried out only within intervals during which the relative speed between the electrode of the electrode section and the processing surface of a substrate in the width direction of the electrode section is fast, for example, not lower than 0.2 m/sec, preferably not lower than 0.5 m/sec, more preferably not lower than 0.7 m/sec, the amount of gas bubbles generated at the gas generation sites can be lowered as in the above-described case of increasing the relative speed.

Also in this case, the ion exchanger 90 and the processing surface of the substrate W preferably contact each other linearly with the contact width W₁ of 0.1 to 1.5 mm, preferably 0.2 to 1.2 mm, more preferably 0.2 to 1.0 mm. Further, the contact time of the electrode (ion exchanger) with a point in the processing surface of the substrate is generally not more than 10 msec, preferably not more than 5 msec, and more preferably not more than 1.5 msec.

Table 2 below shows the results of a calculation of scroll radius (mm), scroll rotational speed N (rpm), angle of rotation θ (deg) and contact width L (mm), as calculated on the assumption that: θa=45° (ON/OFF duty 50%) or 30° (ON/OFF duty 30%); the minimum relative speed v during “ON” is 0.2 m/s; and the maximum contact time is 1.5 msec.

TABLE 2

| | | | | | |
|---|---|---|---|---|---|
| r: mm | 10 | 20 | 30 | 10 | 30 |
| N: rpm | 300 | 150 | 100 | 720 | 240 |
| θ: deg | 45 | 45 | 45 | 30 | 30 |
| L: mm | 1 | 1 | 1 | 1 | 1 |
| v(θ): m/s | 0.2 | 0.2 | 0.2 | 0.7 | 0.7 |
| T: msec | 4.5 | 4.5 | 4.5 | 1.5 | 1.5 |

As described hereinabove, according to the present invention, instead of a CMP processing, for example, electrolytic processing of a workpiece, such as a substrate, can be effected through an electrochemical action without causing any physical defects in the workpiece that would impair the properties of the workpiece. Accordingly, the present invention can omit a CMP processing entirely or at least reduce a load upon CMP. Further, the present invention can effectively remove (clean) matter adhering to the surface of the workpiece. Further, the electrolytic processing of a substrate can be effected even by solely using pure water or ultrapure water. This obviates the possibility that impurities such as an electrolyte will adhere to or remain on the surface of the substrate, can simplify a cleaning process after the removal processing, and can remarkably reduce a load upon waste liquid disposal. Furthermore, the present invention can prevent the formation of pits in a workpiece which would impair the product quality.

FIG. 31 is a plan view showing the construction of a substrate processing apparatus provided with an electrolytic processing apparatus for carrying out an electrolytic processing method according to the present invention. As shown in FIG. 31, the substrate processing apparatus comprises a pair of loading/unloading section 30 as a carry-in/carry-out section for carrying in and out a substrate, e.g. a substrate W as shown in FIG. 1B, a first cleaning machine 31a for performing a primary cleaning of the substrate, a second cleaning machine 31b for performing a secondary cleaning (finish cleaning) of the substrate, a reversing machine 32 for reversing the substrate, and an electrolytic processing apparatus 34a. These devices are disposed in series. A transport robot 36 as a transport device, which can move parallel to these devices for transporting and transferring the substrate W therebetween, is provided. The substrate processing apparatus is also provided with a control section 38a, disposed adjacent to the loading/unloading units 30, for controlling a rotational speed of an electrode portion 46 based on the output from an eddy current sensor 200, as described below.

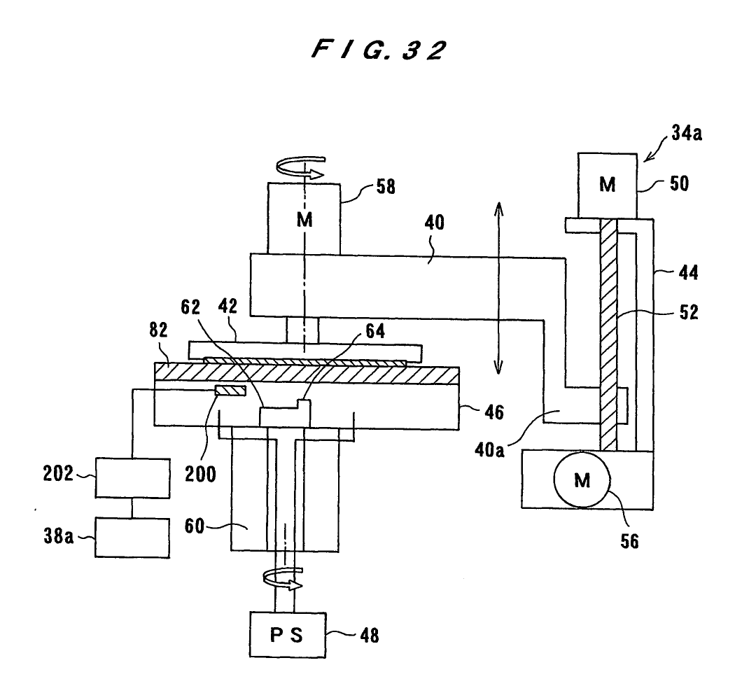

FIG. 32 is a vertical sectional view of the electrolytic processing apparatus 34a provided in the substrate processing apparatus. The electrolytic processing apparatus 34a differs from the above-described electrolytic processing apparatus shown in FIGS. 15 through 20 in the following respects. An eddy current sensor 200 is embedded in the electrode section 46 of the electrolytic processing apparatus 34a. The eddy current sensor 200 generates an eddy current within a conductive film, such as a copper film 6 (see FIG. 1B), deposited on a surface of a substrate W and detects the intensity of the eddy current generated. A detected signal from the eddy current sensor 200 is inputted into a signal processor 202 as a film thickness detection section, and a processed signal from the signal processor 202 is inputted into a control section 38a.

The eddy current sensor 200 has a sensor coil, and generates an eddy current within a conductive film, such as the copper film 6 deposited on the surface of the substrate W, by flowing a high-frequency electric current through the sensor coil. The intensity of the eddy current generated changes with the thickness of the conductive film such as the copper film 6.

According to this embodiment, the intensity of an eddy current generated within a conductive film, such as the copper film 6 deposited on the surface of the substrate W, is detected with the eddy current sensor 200, and a detected signal from the eddy current sensor 200 is sent to the signal processor 202. When, for example, the signal processor 202 detects a change in the intensity of eddy current having reached a predetermined value, it decides that the thickness of the (remaining) conductive film, such as the copper film 6, on the substrate W has reached a predetermined value, thus detecting the endpoint of processing. The signal processor 202 on detection of the end point of processing, sends a predetermined signal to the control section 38.

Next, substrate processing (electrolytic processing) by using the electrolytic processing apparatus will be described. First, a substrate W, e.g. a substrate W, as shown in FIG. 1B, which has in its surface a copper film 6 as a conductive film (to-be-processed portion), is taken by the transport robot 36 out of the cassette housing substrates and set in the loading/unloading section 30. If necessary, the substrate W is transferred to the reversing machine 32 by the transport robot 36 to reverse the substrate W so that the front surface of the substrate W having the conductor film (copper film 6) faces downwardly.

Then, the transport robot 36 receives the reversed substrate W and transfers it to the electrolytic processing apparatus 34a. The substrate W is attracted and held by the substrate holder 42. The arm 40 is moved to move the substrate holder 42 holding the substrate W to a processing position right above the electrode section 46. Next, the vertical-movement motor 50 is driven to lower the substrate holder 42 so as to bring the substrate W held by the substrate holder 42 close to or into contact with the surface of the ion exchangers 90 of the electrode section 46. Thereafter, the substrate-rotating motor 58 is driven to rotate the substrate and, at the same time, the hollow motor 60 is driven to make the electrode section 46 a scroll movement so that the substrate W and the electrode section 46 make a relative movement. At this time, pure water or ultrapure water is jetted from the jet ports 98 of the pure water jet nozzles 96 to between the substrate W and the electrode members 82, and pure water or ultrapure water is supplied to the ion exchangers 88 through the through-holes 100 of the electrode section 46. In this embodiment, pure water or ultrapure water supplied to the ion exchangers 88 is discharged from the end portion in the longitudinal direction of each electrode member 82.

Then, a given voltage is applied from the power source 48 to between the processing electrodes and the feeding electrodes, and electrolytic processing of the conductive film (copper film 6) in the surface of the substrate W is carried out at the processing electrodes (cathodes) through the action of hydrogen ions or hydroxide ions produced by the ion exchangers 88, 90. According to this embodiment, processing is carried out by rotating the substrate holder 42 and, at the same time, allowing the electrode section to make scroll movement. The arm 40 and the substrate holder 42 may be moved in Y direction by the actuation of the reciprocating motor 56 during electrolytic processing.

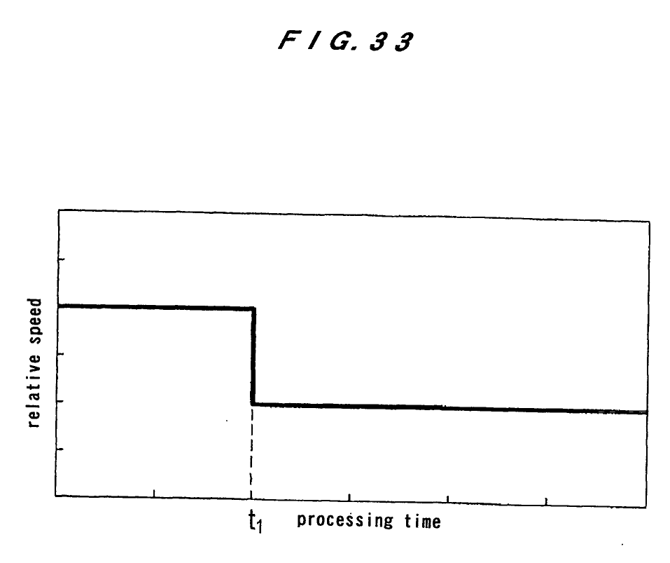

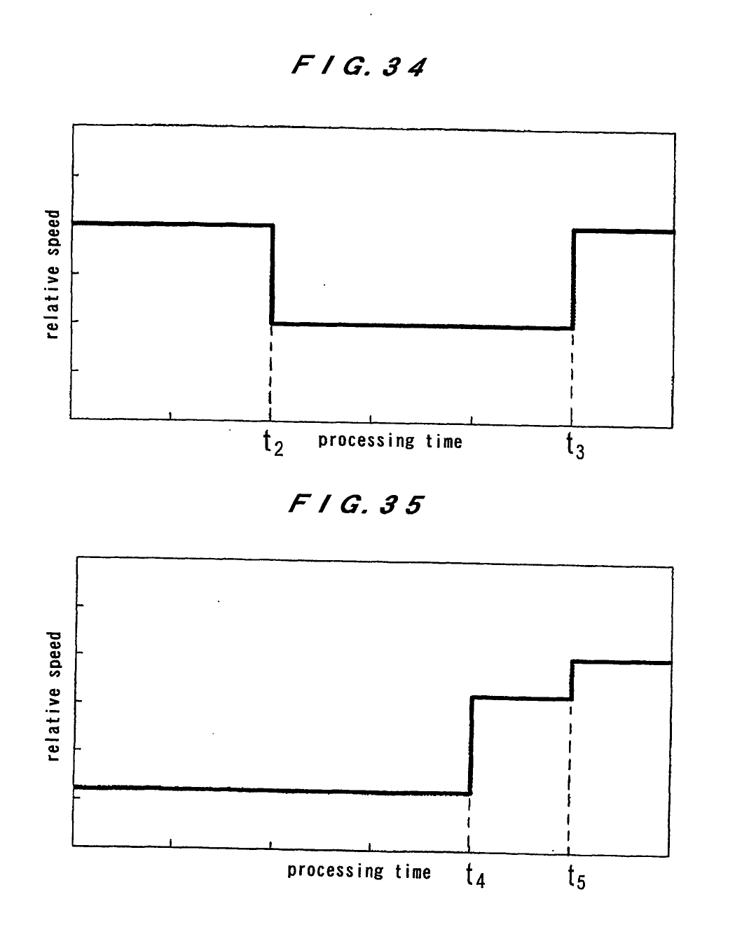

As shown in FIG. 33, in an initial stage of electrolytic processing (−t₁), the relative speed between the substrate W held by the substrate holder 42 and each electrode 86 is made fast by, for example, making the scroll movement speed of the electrode section 46 fast. For example, the relative speed is made not lower than 0.4 m/sec, preferably not lower than 0.5 m/sec, more preferably not lower than 0.6 m/sec. By thus making the relative speed between the substrate W held by the substrate holder 42 and each electrode 86 fast, the processing rate can be made low, as described previously. This enhances the effect of eliminating a level difference upon removal and flattening of a thin film, for example the copper film 6 shown in FIG. 1B, formed on the substrate W.

When the eddy current sensor 200 detects a thickness of the remaining copper film 6 having reached a predetermined value, for example, not more than 600 nm, preferably not more than 500 nm, more preferably not more than 400 nm, the sensor 200 sends the signal to the signal processor 202. Based on the processed signal from the signal processor 202 the control section 38, slows down, for example, the scroll movement speed of the electrode section 46 so that the relative speed between the substrate W held by the substrate holder 42 and each electrode 86 becomes slow in a later processing stage (t₁−), as shown in FIG. 33. Lowering the relative speed between the substrate W and each electrode 86 increases the processing rate, as described previously. An initial level difference in the processing surface is generally 300 to 500 nm. The shift of the relative speed for increasing the processing rate is made before complete elimination of the initial level difference, i.e., before removal by processing of the film thickness corresponding to the initial level difference.

Thus, in the initial processing stage (−t₁), the effect of eliminating a level difference can be enhanced by using a high relative speed between the substrate W and the electrode 86, while in the later stage (t₁−) when the level difference has been eliminated, the processing rate can be increased by lowering the relative speed between the substrate W and the electrode 86. This manner of processing can thus attain enhancement of the level difference elimination effect and shortening of the processing time.

After completion of the electrolytic processing, the power source 48 is disconnected, and the rotation of the substrate holder 42 and the electrode section 46 are stopped. Thereafter, the substrate holder 42 is raised, and substrate W is transferred to the transport robot 36 after moving the arm 40. The transport robot 3 6 takes the substrate W from the substrate holder 42 and, if necessary, transfers the substrate W to the reversing machine 32 for reversing it. The transport robot 36 then transports the substrate W to the first cleaning machine 31a, where a primary cleaning of the substrate is carried out. The substrate W is then transported to the second cleaning machine 31b with the transport robot 36, where a secondary cleaning (finish cleaning) of the substrate is carried out. The substrate W is then dried, and the dried substrate W is returned to the cassette of the loading/unloading section 30.

It is to be noted here that when a liquid like ultrapure water which itself has a large resistivity is used, the electric resistance can be lowered by bringing the ion exchanger 90 into contact with the substrate W, whereby the requisite voltage can also be lowered and hence the power consumption can be reduced. The “contact” does not imply “press” for giving a physical energy (stress) to a workpiece as in CMP. Accordingly, the electrolytic processing apparatus of this embodiment employs the vertical-movement motor 50 for bringing the substrate W into contact with or close to the electrode section 46, and does not have such a press mechanism as usually employed in a CMP apparatus that presses a substrate against a polishing member. In this regard, according to a CMP apparatus, a substrate is pressed against a polishing surface generally at a pressure of about 20-50 kPa, whereas in the electrolytic processing apparatus of this embodiment, the substrate W may be contacted with the ion exchanger 90 at a pressure of less than 20 kPa, for example. Even at a pressure less than 10 kPa, a sufficient removal processing effect can be achieved.

Though in this embodiment the relative speed between the substrate W and the electrode 86 is made fast in the initial processing stage and slow in the later processing stage. It is also possible to make the relative speed between the substrate W and the electrode 86 fast in an initial processing stage (−t₂), slow in an intermediate processing stage (t₂−t₃), and again fast in a later processing stage (t₃ −), as shown in FIG. 34.

In particular, the relative speed between the substrate W held by the substrate holder 42 and each electrode 86 is made fast by, for example, making the scroll movement speed of the electrode section 46 fast in the initial stage of electrolytic processing (−t₂) so as to lower the processing rate, thereby enhancing the effect of eliminating a level difference upon removal and flattening of a thin film, for example the copper film 6 shown in FIG. 1B, formed on the substrate W.

In the intermediate processing stage (t₂−t₃) after the eddy current sensor 200 detects a thickness of the remaining copper film 6 having reached a predetermined value, for example, not more than 600 nm, preferably not more than 500 nm, more preferably not more than 400 nm, the relative speed between the substrate W held by the substrate holder 42 and each electrode 86 is made slow by, for example, slowing down the scroll movement speed of the electrode section 46, thereby increasing the processing rate. The relative speed in this stage is made slower than the relative speed immediately before. Specifically, the relative speed in this stage is made not higher than 0.4 m/sec, preferably not higher than 0.3 m/sec, more preferably not higher than 0.2 m/sec.

Further, in the later processing stage (t₃−) after the eddy current sensor 200 detects a thickness of the remaining copper film 6 having reached a predetermined value, for example, 50 to 300 nm, preferably 50 to 200 nm, more preferably 50 to 150 nm, the relative speed between the substrate W held by the substrate holder 42 and each electrode 86 is again made fast by, for example, speeding up the scroll movement of the electrode section 46 to enhance the level difference elimination effect and carry out finish processing while preventing the formation of pits in the processing surface.

By thus making the relative speed between the substrate W and each electrode 86 fast in the later processing stage (t₃−), it becomes possible to further enhance the level difference elimination effect and prevent the formation of pits in the processing surface. In this regard, it has been confirmed that when carrying out electrolytic processing while allowing the electrode section 46 and the substrate W held by the substrate holder 42 to make a relative movement in such a manner that the electrode section 46 makes a scroll movement and the substrate W is rotated, as in this embodiment, the formation of pits during processing of a conductive film, for example the copper film 6 shown in FIG. 1B, on the substrate W can be prevented by making the relative speed between the electrode 86 and the substrate W not lower than 0.4 m/sec, preferably not lower than 0.5 m/sec, more preferably not lower than 0.6 m/sec. Further, by thus lowering the processing rate in the later processing stage, the end point of processing can be detected more precisely.

It is not necessary to make the relative speed between the substrate W and each electrode 86 in the later stage equal to that in the initial stage. The relative speed in the later stage may differ, for example faster, from the relative speed in the initial stage, depending upon the intended purpose.

Further, as shown in FIG. 35, it is also possible to make the relative speed between the substrate W and each electrode 86 slow in an initial processing stage (−t₄), fast in an intermediate processing stage (t₄−t₅) and, according to necessity, faster in a later processing stage (t₅−) than the intermediate processing stage (t₄−t₅).

In particular, the relative speed between the substrate W held by the substrate holder 42 and each electrode 86 is made slow by, for example, making the scroll movement speed of the electrode section 46 slow in the initial stage of electrolytic processing (−t₄) so as to increase the processing rate. In the intermediate processing stage (t₄−t₅) after the eddy current sensor 200 detects a thickness of the remaining film, for example the copper film 6 shown in FIG. 1B, formed on the substrate W having reached a predetermined value, for example not more than 500 nm, preferably not more than 400 nm, more preferably not more than 300 nm, the relative speed between the substrate W held by the substrate holder 42 and each electrode 86 is made fast by, for example, speeding up the scroll movement of the electrode section 46, thereby enhancing the level difference elimination effect upon removal and flattening of e.g. the copper film 6. This manner of electrolytic processing can also attain enhancement of the level difference elimination and shortening of the processing time.

Further, the formation of pits in the processing surface can be prevented by thus making the relative speed between the substrate W and each electrode 86 fast in the intermediate processing stage. In addition, the level difference elimination effect and the effect of preventing the formation of pits in the processing surface can be further enhanced by making the relative speed faster in the later processing stage (t₅−) than the intermediate processing stage (t₄−t₅).

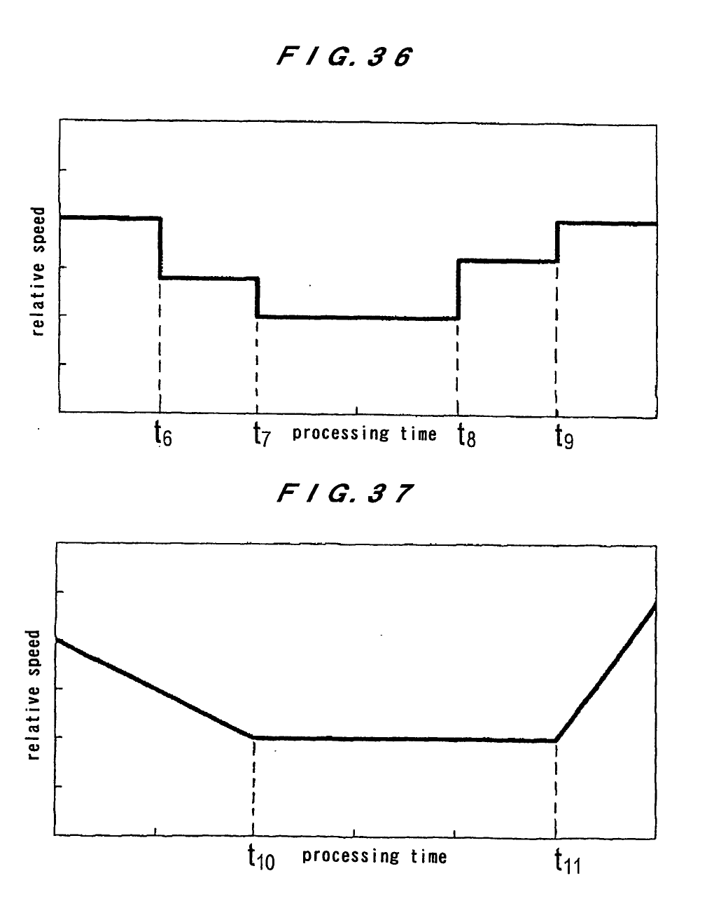

Further, as shown in FIG. 36, it is also possible to make the relative speed between the substrate W and the electrode 86 in electrolytic processing fast in an initial processing stage (−t₇) in which a thickness of the remaining film becomes not more than 600 nm, preferably not more than 500 nm, more preferably not more than 400 nm, slow in an intermediate processing stage (t₇−t₈) in which a thickness of the remaining film becomes 50 to 300 nm, preferably 50 to 200 nm, more preferably 50 to 150 nm, and again fast in an later processing stage (t₈−); and make the relative speed slower during a later period (t₆−t₇) of the initial processing stage (−t₇) than the earlier period (−t₆) so as to earn the processing rate, and make the relative speed faster in the later period (t₉−) of the later processing stage (t₈−) than the earlier period (t₈−t₉) so as to further enhance the level difference elimination effect and the effect of preventing the formation of pits in the processing surface.

Though in the above examples the relative speed between the substrate W and the electrode 86 is changed stepwise, it is also possible to change the relative speed in a continuous or gradual manner. For example, as shown in FIG. 37, in carrying out electrolytic processing in such a manner that the relative speed between the substrate W and the electrode 86 is made fast in an initial processing stage (−t₁₀), slow in an intermediate processing stage (t₁₀−t₁₁), and again fast in a later processing stage (t₁₁−), it is possible to linearly decrease the relative speed between the substrate W and the electrode 86 in the initial processing stage (−t₁₀), and linearly increase the relative speed between the substrate W and the electrode 86 in the later stage of processing (t₁₁−). The inclination of the relative speed decrease line in the initial processing stage (−t₁₀) and the inclination of the relative speed increase line in the later processing stage (t₁₁−) may be set arbitrarily.

Though in this example the relative speed between the substrate W and the electrode 86 is decreased or increased linearly, it is also possible to decrease or increase the relative speed between the substrate W and the electrode 86 in a curve.

According to this embodiment, the timing of making a shift of the relative speed is detected by measuring a thickness of e.g. the remaining copper film 6 shown in FIG. 1B with the eddy current sensor 200. The timing of a shift of the relative speed may also be detected by (1) calculating the processing time from a pre-measured initial film thickness and the processing rate, (2) fixing one of the applied current and voltage and measuring a change of the other, (3) measuring the torque of the hollow motor 60 rotating the electrode section 46 or measuring a change in the torque per unit time, or (4) measuring the film thickness with an optical means. It is also possible to determine a shift processing amount/thickness of remaining film for a switch of the relative speed by a trial-and-error method, without previously measuring the relationship between processing amount and level difference, in order to optimize the level difference after processing. Further, electrolytic processing may be carried out while measuring the thicknesses of various films in situ, and changing not only the relative speed but also the applied voltage and/or the contact pressure between the substrate W and the electrode 86 (ion exchanger 90).

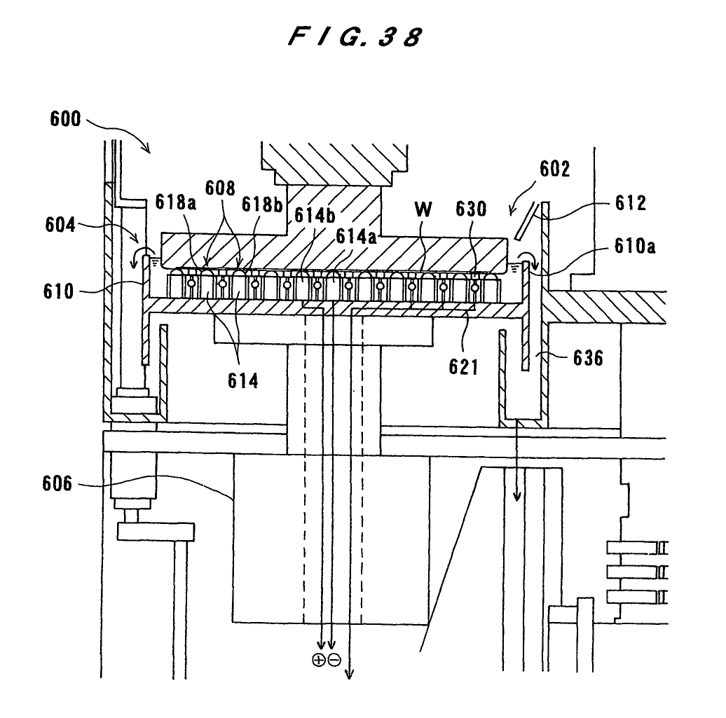

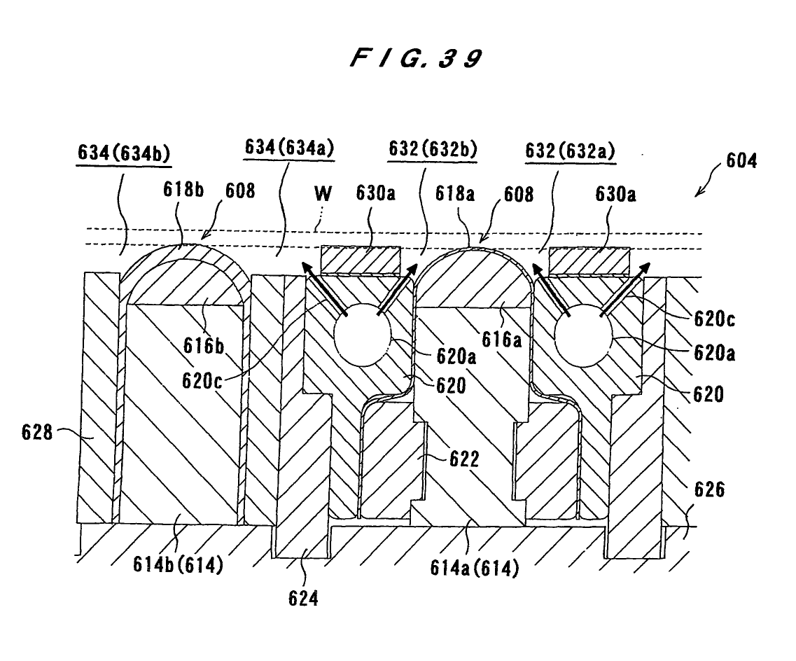

FIG. 38 is a vertical sectional view showing the main portion of another electrolytic processing apparatus suited for carrying out an electrolytic processing method according to the present invention, and FIG. 39 is an enlarged view of the main portion of FIG. 38. As shown in FIG. 38, the electrolytic processing apparatus 600 includes a substrate holder 602 for holding a substrate W with its front surface facing downwardly, and a rectangular electrode section 604 provided below the substrate holder 602. The substrate holder 602, as with the examples described above, is rotatable and movable vertically and horizontally. The electrode section 604 is provided with a hollow scroll motor 606 and, by the actuation of the scroll motor 606, makes a circular movement without rotation, a so-called scroll movement (translational rotary movement).

The electrode section 604 includes a plurality of linearly-extending electrode members 608 and a vessel 610 which opens upwardly. The plurality of electrode members 608 are disposed in parallel at an even pitch in the vessel 610. Further, positioned above the vessel 610, a liquid supply nozzle 612 is disposed for supplying liquid, such as ultrapure water or pure water, into the vessel 610. The electrode members 608 each includes an electrode 614 to be connected to a power source in the apparatus. The electrodes 614 are connected alternately to the cathode and to the anode of the power source, that is, processing electrodes 614a are connected to the cathode of the power source and feeding electrodes 614b are connected to the anode of the power source. Thus, as described above, when processing copper, for example, the electrolytic processing action occurs on the cathode side, and therefore the electrodes 614 connected to the cathode of the power source becomes processing electrodes 614a and the electrodes 614 connected to the anode of the power source becomes feeding electrodes 614b.

With respect to of each processing electrode 614a connected to the cathode, as shown in detail in FIG. 39, an ion exchanger 616a composed e.g. of a non-woven fabric is mounted on the upper portion of the electrode. The processing electrode 614a and the ion exchanger 616a are covered integrally with a second ion exchanger 618a composed of ion exchange membrane which shuts off permeation therethrough of a liquid and permits only ions to pass therethrough. Similarly, an ion exchanger 616b composed e.g. of a non-woven fabric is mounted on the upper portion of each feeding electrode 614b to be connected to the anode, and the feeding electrode 614b and the ion exchanger 616b are covered integrally with a second ion exchanger 618b composed of ion exchange membrane which shuts off permeation therethrough of a liquid and permits only ions to pass therethrough.

Accordingly, ultrapure water or a liquid passes through through-holes (not shown) provided at certain locations along the long direction of the electrode 614 and can move freely within the ion exchanger 616a or 616b composed of a non-woven fabric and easily reach the active points, having water dissociation catalytic activity, within the non-woven fabric, while the flow of the liquid is shut off by the ion exchanger 618a or 618b composed of ion exchange membrane, which constitutes the below-described second partition.

A pair of liquid supply nozzles 620 is disposed on both sides of each processing electrode 614a connected to the cathode of the power source. In the interior of each liquid supply nozzle 620, a liquid flow passage 620a, extending in the long direction, is provided, and liquid supply holes 620c, which opens upward and communicates with the liquid flow passage 620a, are provided at certain locations along the long direction.

The processing electrode 614a and the pair of liquid supply nozzles 620 are integrated by a pair of tap bars 622, and held between a pair of insert plates 624 and fixed on a base 626. On the other hand, the feeding electrode 614b, with its surface covered with the ion exchanger 618b, is held between a pair of holding plates 628 and fixed on the base 626.

The ion exchangers 616a, 616b are, for example, composed of a non-woven fabric having an anion exchange group or a cation exchange group. As described above, it is possible to use a laminate of an anion exchanger having an anion exchange group and a cation exchanger having a cation exchange group, or impart both of anion exchange group and cation exchange group to the ion exchangers 616a, 616b themselves. A polyolefin polymer, such as polyethylene or polypropylene, or other organic polymers may be used as the base material of the ion exchangers. With respect to the base material of the electrodes 614 of the electrode members 608, rather than metals or metal compounds widely used for electrodes, it is preferred to use carbon, a relatively inactive noble metal, a conductive oxide or a conductive ceramic, as also described above.

A partition 630a, composed of e.g. a resin having elasticity, is mounted on the upper surface of each liquid supply nozzle 620 over the full length in the long direction. A thickness of the partition 630a is set at such a thickness that when the substrate W held by the substrate holder 602 is brought close to or into contact with the ion exchangers 618a, 618b of the electrode members 608 to carry out electrolytic processing of the substrate W, the upper surface of the partition 630a comes into pressure contact with the substrate W held by the substrate holder 602.

Accordingly, upon electrolytic processing, flow paths 632 formed between the processing electrodes 614a and the substrate W, and flow paths 634 formed between the feeding electrodes 614b and the substrate W, which are separated by the partitions 630a, are formed in parallel between the electrode section 604 and the substrate holder 602. Further, each flow path 632 formed between the processing electrode 614a and the substrate W is separated into two flow paths 632a, 632b by the ion exchanger 618a as a second partition composed of an ion exchange membrane, while each flow path 634 formed between the feeding electrode 614b and the substrate W is separated into two flow paths 634a, 634b by the ion exchanger 618b as a second partition composed of an ion exchange membrane.

According to this embodiment, upon electrolytic processing, the vessel 610 is filled with a liquid, such as ultrapure water or pure water, supplied from the liquid supply nozzle 612, while a liquid, such as ultrapure water or pure water, is kept supplied from the through-holes (not shown) provided in the electrodes 614 to the ion exchangers 616a, 616b composed of a non-woven fabric disposed on the upper portions of the processing electrodes 614a and the feeding electrodes 614b. An overflow channel 636 for discharging the liquid that has overflowed a circumferential wall 610a of the vessel 610 is provided outside the vessel 610. The liquid that has overflowed the circumferential wall 610a flows through the overflow channel 636 into a waste liquid tank (not shown).

In this embodiment, a pair of liquid supply nozzles having liquid supply holes provided at certain locations along the long direction is disposed on both sides of each processing electrode, and a liquid is supplied form the liquid supply nozzles. With this arrangement, it becomes possible to more securely control the flow of the liquid flowing along the flow paths 632 formed between the processing electrodes 614a and the substrate W and the flow of the liquid flowing along the flow paths 634 formed between the feeding electrodes 614b and the substrate, and decrease the amount of the liquid that flows across the partitions into the adjacent spaces. It is also possible to make a flow of the liquid flowing along electrodes by pushing out the liquid along the long direction of the electrodes.

In the above-described embodiments that show the case of mounting an ion exchanger on the electrode, the shape of the electrode and the liquid for use in processing are not particularly limited provided that the contact member or the partition can be provided between adjacent electrodes. Thus, the shape of electrode is not limited to a bar-like shape, but any shape of electrode can be selected, and a plurality of such electrodes may be disposed so that they will be opposed to a workpiece. It is possible to mount a water-permeable scrub member other than an ion exchanger on the electrode. Further, it is possible to make the contact member or the partition higher than the electrode surface, thereby preventing direct contact between a workpiece and the electrode and making the surface of the electrode exposed. Even in the case of not mounting an ion exchanger on the surface of the electrode, the second partition for partitioning the flow of the liquid between a workpiece and the electrode is preferably provided.

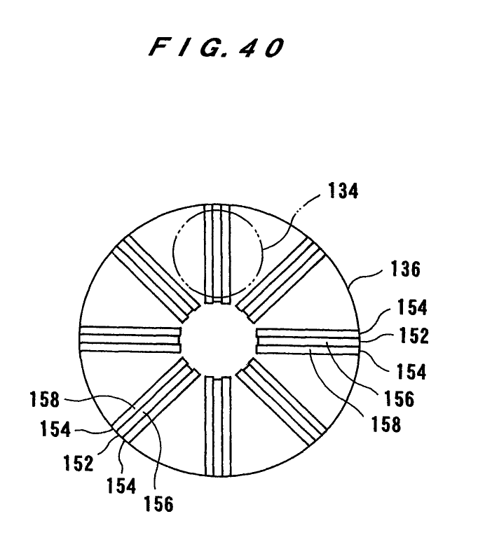

FIG. 40 schematically shows a still another electrolytic processing apparatus suited for carrying out an electrolytic processing method according to the present invention. The electrolytic processing apparatus includes a substrate holder 134 for detachably holding a substrate, and a rotatable electrode section 136 provided below the substrate holder 134 and having a diameter which is more than twice the diameter of the substrate holder 134. A plurality of radially-extending processing electrodes 152 are provided on the upper surface of the electrode section 136, and a pair of linearly-extending feeding electrodes 154 is disposed on both sides of each processing electrode 152. A contact member 156 comprised of, for example, an ion exchanger is provided on the upper surface (front surface) of each processing electrode 152, and a contact member 158 comprised of, for example, an ion exchanger is provided also on the upper surface (front surface) of each feeding electrode 154.

In this embodiment, the processing electrodes 152 are connected to the cathode of a power source via a not-shown slip ring, while the feeding electrodes 154 are connected to the anode of the power source via a not-shown slip ring. This is because in processing of copper, the electrolytic processing action occurs on the cathode side. As described previously, depending upon the material to be pressed, the cathode side may serve as a feeding electrode and the anode side may serve as a processing electrode.

According to this embodiment, the substrate holder 134 in a predetermined position above the electrode section 136 is lowered to bring a substrate W held by the substrate holder 134 into contact with the contact members 156, 158.covering the surfaces of the processing electrodes 152 and the feeding electrodes 154 mounted on the upper surface of the electrode section 136. Thereafter, the substrate holder 134 and the electrode section 136 are rotated (about their axes) while applying a predetermined voltage from the power source to between the processing electrodes 152 and the feeding electrodes 154, and supplying pure water, preferably ultrapure water, between the substrate W held by the substrate holder 134 and the contact members 156, 158, thereby effecting electrolytic processing of the surface of the substrate W.

According to the electrolytic processing apparatus of this embodiment, electrolytic processing can be carried out by simply rotating the electrodes (processing electrodes 152 and feeding electrodes 154) and a substrate held by the substrate holder 134 while keeping the relative speed therebetween constant. Further, the relative speed between the electrodes (processing electrodes 152 and feeding electrodes 154) and the substrate can be made faster as compared to scroll movement.

While the present invention has been described with reference to the preferred embodiments thereof, the present invention is not limited to such embodiments and changes and modifications could be made within the technical concept of the invention.

### INDUSTRIAL APPLICABILITY

The electrolytic processing apparatus and electrolytic processing method of the present invention can advantageously be used for processing a conductive material formed on a substrate, such as a semiconductor wafer, or removing impurities adhering to the surface of the substrate.

1-18. (canceled)

19. An electrolytic processing apparatus comprising:
an electrode section including an electrode member comprised of an electrode and an ion exchanger covering a surface of the electrode;
a holder for holding a workpiece and bringing the workpiece into contact with the ion exchanger of the electrode member;
a liquid supply system for supplying a liquid between the ion exchanger and the workpiece held by the holder;
a drive mechanism for causing relative movement between the electrode section and the workpiece; and
a power source to be connected to the electrode of the electrode member of the electrode section;
wherein a continuous contact time of the ion exchanger with a point in a processing surface of the workpiece is not more than 10 msec.

20. The electrolytic processing apparatus according to claim 19, wherein the drive mechanism is designed to cause relative movement between the electrode section and the workpiece at a relative speed of not lower than 0.2 m/sec.

21. The electrolytic processing apparatus according to claim 19, wherein the ion exchanger covering the electrode is designed to make contact with the workpiece held by the holder with a contact width of 0.2 to 1.5 mm.

22. The electrolytic processing apparatus according to claim 21, wherein the drive mechanism is designed to cause relative movement between the electrode section and the workpiece at a relative speed of not lower than 0.2 m/sec.

23-38. (canceled)

39. An electrolytic processing method comprising:
processing a workpiece in the presence of a liquid by applying a voltage to an electrode and moving an ion exchanger, covering a surface of the electrode, and the workpiece held by a holder relative to each other, while keeping the ion exchanger and the workpiece in contact with each other, such that the contact time of the ion exchanger with a point in a processing surface of the workpiece is not more than 10 msec.

40. The electrolytic processing method according to claim 39, wherein the ion exchanger and the workpiece held by the holder contact each other with a contact width of 0.2 to 1.5 mm.

41. The electrolytic processing method according to claim 39, wherein the ion exchanger and the workpiece held by the holder are moved relative to each other at a relative speed of not less than 0.2 m/sec while keeping them in linear contact with each other.

42. The electrolytic processing method according to claim 40, wherein the ion exchanger and the workpiece held by the holder are moved relative to each other at a relative speed of not less than 0.2 m/sec while keeping them in linear contact with each other.

43-71. (canceled)
